(19) United States
(12) Patent Application Publication
(10) Pub. No.: US 2005/0227382 A1
(43) Pub. Date: Oct. 13, 2005

(54) In-situ surface treatment for memory cell formation

(76) Inventor: Angela T. Hui, Fremont, CA (US)

Correspondence Address: AMIN & TUROCY, LLP, 1900 EAST 9TH STREET, NATIONAL CITY CENTER, 24TH FLOOR,, CLEVELAND, OH, 44114, US

(21) Appl. No.: 10/817,131

(22) Filed: Apr. 2, 2004

(51) Int. Cl. H01L 21/66

(52) U.S. Cl. 438/14

(57) ABSTRACT

A system and methodology are disclosed for forming a passive layer on a conductive layer, such as can be done during fabrication of an organic memory cell, which generally mitigates drawbacks inherent in conventional inorganic memory devices. The passive layer includes a conductivity facilitating compound, such as copper sulfide (Cu₂S), which is generated from an upper portion of a conductive material. The conductive material can serve as a bottom electrode in the memory cell, and the upper portion of the conductive material can be transformed into the passive layer via treatment with a plasma generated from fluorine (F) based gases.

### FIELD OF INVENTION

The present invention relates generally semiconductor fabrication and, in particular, to a system and methodology for forming a conductivity facilitating layer for an organic memory cell via plasma treatment.

### BACKGROUND OF THE INVENTION

In the semiconductor industry there is a continuing trend toward increasing device densities, throughput and yield. To increase device densities there have been, and continue to be, efforts toward scaling down semiconductor device dimensions (e.g., at sub-micron levels). In order to accomplish such densities, smaller feature sizes and more precise feature shapes are required. This may include the width and spacing of interconnecting lines, spacing and diameter of contact holes, and the surface geometry, such as comers and edges, of various features. To increase throughput, the number of required processing steps can be reduced and/or the time required for those processing steps can be reduced. To increase yield, which is the percentage of finished products that leave a fabrication process as compared to the number of products that enter the fabrication process, control and/or quality of individual fabrication processes can be improved.

Semiconductor fabrication is a manufacturing process employed to create semiconductor devices in and on a wafer surface. Polished, blank wafers come into semiconductor fabrication, and exit with the surface covered with large numbers of semiconductor devices. Semiconductor fabrication includes a large number of steps and/or processes that control and build the devices—basic processes utilized include layering, doping, heat treatments and patterning. Layering is an operation that adds thin layers to the wafer surface. Layers can be, for example, insulators, semiconductors and/or conductors and are grown or deposited via a variety of processes. Common deposition techniques include, for example, evaporation and sputtering. Doping is a process that adds specific amounts of dopants to the wafer surface. The dopants can cause the properties of layers to be modified (e.g., change a semiconductor to a conductor). A number of techniques, such as thermal diffusion and ion implantation can be employed for doping. Heat treatments are another basic operation in which a wafer is heated and cooled to achieve specific results. Typically, in heat treatment operations, no additional material is added or removed from the wafer, although contaminates and vapors may evaporate from the wafer. One common heat treatment is annealing, which repairs damage to crystal structure of a wafer/device generally caused by doping operations. Other heat treatments, such as alloying and driving of solvents, are also employed in semiconductor fabrication.

The volume, use and complexity of computers and electronic devices are continually increasing as computers are consistently becoming more powerful and new and improved electronic devices are continually developed (e.g., digital audio players, video players). Additionally, the growth and use of digital media (e.g., digital audio, video, images, and the like) have further pushed development of these devices. Such growth and development has vastly increased the amount of information desired/required to be stored and maintained for computer and electronic devices.

Generally, information is stored and maintained in one or more of a number of types of storage devices. Storage devices include long term storage mediums such as, for example, hard disk drives, compact disk drives and corresponding media, digital video disk (DVD) drives, and the like. The long term storage mediums typically store larger amounts of information at a lower cost, but are slower than other types of storage devices. Storage devices also include memory cells which are often, but not always, short term storage mediums. Short term memory cells tend to be substantially faster than long term storage mediums. Such short term memory cells include, for example, dynamic random access memory (DRAM), static random access memory (SRAM), double data rate memory (DDR), fast page mode dynamic random access memory (FPMDRAM), extended data-out dynamic random access memory (EDODRAM), synchronous dynamic random access memory (SDRAM), VideoRAM (VRAM), flash memory, read only memory (ROM), and the like.

Memory cells can generally be subdivided into volatile and non-volatile types. Volatile memory cells usually lose their information if they lose power and typically require periodic refresh cycles to maintain their information. Volatile memory cells include, for example, random access memory (RAM), DRAM, SRAM and the like. Non-volatile memory cells maintain their information whether or not power is maintained to the devices. Non-volatile memory cells include, but are not limited to, ROM, programmable read only memory (PROM), erasable programmable read only memory (EPROM), electrically erasable programmable read only memory (EEPROM), flash EEPROM the like. Volatile memory cells generally provide faster operation at a lower cost as compared to non-volatile memory cells.

Memory cells often include arrays of memory cells. Each memory cell can be accessed or “read”, “written”, and “erased” with information. The memory cells maintain information in an “off” or an “on” state, also referred to as “0” and “1”. Typically, a memory cell is addressed to retrieve a specified number of byte(s) (e.g., 8 memory cells per byte). For volatile memory cells, the memory cells must be periodically “refreshed” in order to maintain their state. Such memory cells are usually fabricated from semiconductor devices that perform these various functions and are capable of switching and maintaining the two states. The devices are often fabricated with inorganic solid state technology, such as, crystalline silicon devices. A common semiconductor device employed in memory cells is the metal oxide semiconductor field effect transistor (MOSFET).

The proliferation and increased usage of portable computer and electronic devices has greatly increased demand for memory cells. Digital cameras, digital audio players, personal digital assistants, and the like generally seek to employ large capacity memory cells (e.g., flash memory, smart media, compact flash, . . . ). The increased demand for information storage is commensurate with memory cells having an ever increasing storage capacity (e.g., increase storage per die or chip). A postage-stamp-sized piece of silicon may, for example, contain tens of millions of transistors, each transistor as small as a few hundred nanometers. However, silicon-based devices are approaching their fundamental physical size limits. Inorganic solid state devices are generally encumbered with a complex architecture which leads to high cost and a loss of data storage density. The volatile semiconductor memories based on inorganic semiconductor material require a near constant supply of electric current, which produces heating and high electric power consumption in order to merely maintain stored information. Non-volatile semiconductor memory cells, which are also based on inorganic semiconductor material, do not require such constant supplies of power in order to maintain stored information. However, non-volatile semiconductor memory cells have a reduced data rate, high power consumption and a large degree of complexity as compared with typical volatile memory cells.

Further, as the size of inorganic solid state devices decreases and integration increases, sensitivity to alignment tolerances can also increase making fabrication markedly more difficult. Formation of features at small minimum sizes does not imply that the minimum size can be used for fabrication of working circuits. It is necessary to have alignment tolerances which are much smaller than the minimum size, such as one quarter the minimum size, for example. Thus, further device shrinking and density increasing may be limited for inorganic memory cells. Furthermore, such shrinkage for inorganic non-volatile memory cells, while meeting increased performance demands, is particularly difficult to do while maintaining low costs.

### SUMMARY OF THE INVENTION

The following presents a simplified summary of the invention in order to provide a basic understanding of some aspects of the invention. This summary is not an extensive overview of the invention. It is intended to neither identify key or critical elements of the invention nor delineate the scope of the invention. Its purpose is merely to present some concepts of the invention in a simplified form as a prelude to the more detailed description that is presented later.

The present invention relates to systems and methodologies for forming organic memory cells, which mitigate drawbacks inherent in conventional inorganic memory devices, such as volatility, limited density and limited device performance capabilities, for example. In according with one or more aspects of the present invention, a portion of an organic memory cell known as a passive layer is formed out of and atop an underlying conductive layer via treatment with plasma. Such a passive layer generally includes a conductivity facilitating compound, such as copper sulfide (Cu₂S), which can be formed out of the conductive layer by treating an upper portion of the conductive layer with plasma, which can be generated from fluorine (F) based gases, for example. The conversion process can be monitored and controlled to facilitate, among other things, formation of the passive layer to a desired thickness, for example.

To the accomplishment of the foregoing and related ends, certain illustrative aspects of the invention are described herein in connection with the following description and the annexed drawings. These aspects are indicative, however, of but a few of the various ways in which the principles of the invention may be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

The present invention is illustrated by way of example in the accompanying figures.

FIG. 1 is a schematic cross sectional illustration of a portion of a wafer depicting a memory cell formed thereon, a portion of which can be formed in accordance with one or more aspects of the present invention.

FIG. 2 is another schematic cross sectional illustration of a portion of a wafer depicting a memory cell formed thereon, a portion of which can be formed in accordance with one or more aspects of the present invention.

FIG. 3 illustrates an array of memory cells, such as may be composed of organic memory cells, portions of which may be formed in accordance with one or more aspects of the present invention.

FIG. 4 is a schematic cross sectional illustration of a substrate and a dielectric layer in fashioning a memory cell in accordance with one or more aspects of the present invention.

FIG. 5 is a schematic cross sectional illustration of fashioning a memory cell similar to that of FIG. 4, including a conductive material and a barrier layer in accordance with one or more aspects of the present invention.

FIG. 6 is schematic cross sectional illustration of fashioning a memory cell similar to that of FIG. 5, including another dielectric layer in accordance with one or more aspects of the present invention.

FIG. 7 is another schematic cross sectional illustration of fashioning a memory cell similar to that of FIG. 6, including forming a passive layer out of an upper portion of the conductive material in accordance with one or more aspects of the present invention.

FIG. 8 is yet another schematic cross sectional illustration of fashioning a memory cell similar to that of FIG. 7, including an organic layer in accordance with one or more aspects of the present invention.

FIG. 9 is still another schematic cross sectional illustration of fashioning a memory cell similar to that of FIG. 8, including another conductive material serving as a top electrode in accordance with one or more aspects of the present invention.

FIG. 10 is a schematic block diagram illustrating a system for forming a passive layer on a conductive layer in the manufacture of one or more memory cells in accordance with one or more aspects of the present invention.

FIG. 11 illustrates a perspective view of a grid mapped wafer according to one or more aspects of the present invention.

FIG. 12 illustrates plots of measurements taken at grid mapped locations on a wafer in accordance with one or more aspects of the present invention.

FIG. 13 illustrates a table containing entries corresponding to measurements taken at respective grid mapped locations on a wafer in accordance with one or more aspects of the present invention.

FIG. 14 is a flow diagram illustrating a method for forming a passive layer atop a conductive material in the manufacture of one or more memory cells in accordance with one or more aspects of the present invention.

FIG. 15 is a graph depicting the effect of an intrinsic electric field on an interface between a conductivity facilitating layer and a polymer layer in accordance with one or more aspects of the present invention.

FIG. 16 is graph illustrating charge carrier distribution of an exemplary memory cell in accordance with one or more aspects of the present invention.

FIG. 17 is another graph illustrating charge carrier distribution of an exemplary memory cell in accordance with one or more aspects of the present invention.

FIG. 18 depicts yet another graph illustrating charge carrier distribution of an exemplary memory cell in accordance with one or more aspects of the present invention.

FIG. 19 is yet another graph illustrating charge carrier distribution of an exemplary memory cell in accordance with one or more aspects of the present invention.

FIG. 20 is a graph illustrating charge carrier concentration at the interface of an exemplary memory cell in accordance with one or more aspects of the present invention.

FIG. 21 is another graph illustrating charge carrier concentration at the interface of an exemplary memory cell in accordance with one or more aspects of the present invention.

### DETAILED DESCRIPTION OF THE INVENTION

The present invention is now described with reference to the drawings, wherein like reference numerals are used to refer to like elements throughout. In the following description, for purposes of explanation, numerous specific details are set forth in order to provide a thorough understanding of the present invention. It may be evident, however, to one skilled in the art that one or more aspects of the present invention may be practiced with a lesser degree of these specific details. In other instances, known structures and devices may be shown in block diagram form in order to facilitate describing one or more aspects of the present invention.

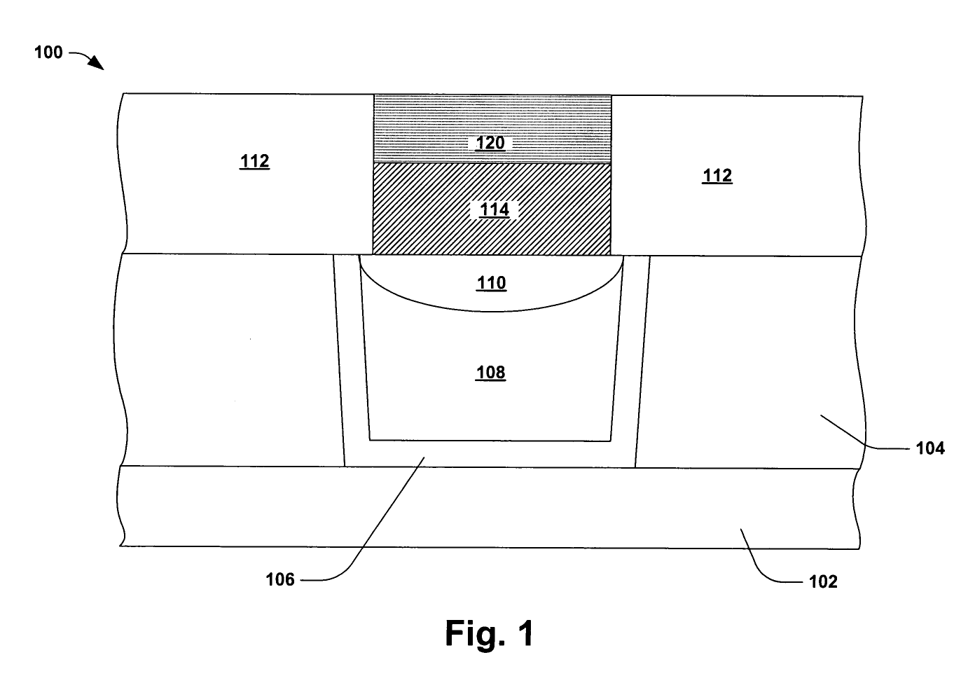

FIG. 1 is a cross sectional illustration of an organic memory cell 100, a portion of which can be formed according to one or more aspects of the present invention. Organic memory cells are memory devices that are, at least partly, based on organic materials and, are thus able to overcome some of the limitations of inorganic based memory devices. Organic memory devices facilitate increased device density while also increasing device performance relative to conventional inorganic memory devices. Additionally, organic memory devices are non-volatile and, as such; do not require frequent refresh cycles or constant or nearly constant power. Organic memory devices can have two or more states corresponding to various levels of impedance. These states are set by applying a bias voltage and then the cells remain in their respective states until another voltage, in reverse bias, is applied. The cells maintain their states with or without power (e.g., non-volatile) and can be read either electrically or optically by measuring injection current or light emission.

Organic memory cells, such as that depicted in FIG. 1, can be formed on a wafer, and typically on a base substrate 102 which generally includes silicon. The organic memory device 100 includes a first dielectric layer 104, a barrier layer 106, a bottom electrode 108, a passive layer 110, a second dielectric layer 112, an organic layer 114 and a top electrode 120. In accordance with one or more aspects of the present invention, the passive layer 110 of the organic memory device 100 is, at least partially, formed by way of a plasma treatment process. The organic memory cell 100 is capable of maintaining two or more states unlike conventional inorganic memory cells which maintain only two states. Thus, a single cell of the organic memory cell 100 can hold one or more bits of information. Furthermore, the organic memory cell 100 is a non-volatile memory cell and consequently, does not require a constant or nearly constant power supply.

The first dielectric layer 104 is formed on the substrate 102, and can be comprised of any type of substance having dielectric or insulating properties. The bottom electrode 108 is formed by depositing a conductive material over the substrate 102. One or more trenches and/or vias can be formed in the dielectric layer 104 prior to deposition of the conductive material, followed by selectively depositing the conductive material into the trench to a level equal to that of the surrounding dielectric layer 104. The conductive layer can also be deposited into the trench to a level greater than the dielectric layer 104, and then be polished back by way of a chemical mechanical polishing (CMP) process so as to be flush with the dielectric layer 104. Typically, some type of patterning/etching process is employed to form the trench(s).

The barrier layer 106 is formed within the trench, including the bottom and sidewalls to mitigate diffusion of the bottom electrode 108 into the dielectric layer 104 and/or the substrate 102. The conductive material of the bottom electrode 108 can include, for example, copper, aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar, Monel®, Inconel®, brass, stainless steel, magnesium-silver alloy, and various other alloys. The bottom electrode 108 can be formed, for example, by a damascene process that includes depositing the conductive material (e.g., by sputtering) and performing a reducing CMP to remove the conductive material from areas outside of the trench.

The passive layer 110 is located atop the bottom electrode 108 and contains at least one conductivity facilitating compound that has the ability to donate and accept charges (holes and/or electrons). Examples of conductivity facilitating compounds that can be employed for the passive layer 106 include one or more of the following: copper sulfide (Cu₂S, CuS), copper oxide (CuO, Cu₂O), manganese oxide (MnO₂), titanium dioxide (TiO₂), indium oxide (I₃O₄), silver sulfide (Ag₂S, AgS), iron oxide (Fe₃O₄), and the like. Generally, the conductivity facilitating compound has at least two relatively stable oxidation-reduction states which permit the conductivity facilitating compound to donate and accept charges.

According to one or more aspects of the present invention, the passive layer 110 can be formed, at least partially, out of an upper portion of the bottom electrode by way of a plasma treatment process whereby some of the conductive material of the bottom electrode 108 is converted to a desired (e.g., conductivity facilitating) material. By way of example, the upper portion of the bottom electrode 108 can be plasma treated with fluorine (F) contained gases, such as CF₄ and/or SF₆, for example, to develop a desired conductivity facilitating material. The passive layer 110 can thus be said to be “grown” from, at least a portion of, the conductive bottom electrode (e.g., copper sulfide grown from copper).

The conductivity facilitating characteristics of the passive layer 110 facilitate transport of charge from the bottom electrode 108 to an interface between the organic layer 114 and the passive layer 110. Additionally, the passive layer 110 facilitates charge carrier (e.g., electrons or holes) injection into the organic layer 114 and increases the concentration of the charge carrier in the organic layer resulting in a modification of the conductivity of the organic layer 114. Furthermore, the passive layer 110 can also store opposite charges in order to balance the total charge of the memory device 100.

The second dielectric layer 112 is selectively formed (e.g., deposited and patterned) over at least a portion of the first dielectric layer 104 and at least a portion of the passive layer 110. The second dielectric layer 112 is patterned so as to allow proper formation of the cell stack, and can be patterned (e.g., etched) prior to plasma treating the copper layer to establish the conductivity facilitating material atop the bottom electrode. The second dielectric layer 112 can be comprised of dielectric materials similar to those employed for the first dielectric layer 104. It is to be appreciated that a combination of the second dielectric layer 112 and the dielectric layer 104 can also be referred to as an inner layer dielectric (ILD).

The organic layer 114 is formed on the passive layer 110. The formation of the organic layer 114 on the passive layer 110 defines the interface between the two layers. The organic layer 114 is typically comprised of a conjugated organic material, such as a small organic molecule and a conjugated polymer. Generally, the conjugated organic molecule has at least two relatively stable oxidation-reduction states, giving it the ability to donate and accept charges (holes and/or electrons). If the organic layer is polymer, a polymer backbone of the conjugated organic polymer may extend lengthwise between the electrodes 108 and 120 (e.g., generally substantially perpendicular to the inner, facing surfaces of the electrodes 108 and 120). The conjugated organic molecule can be linear or branched such that the backbone retains its conjugated nature. Such conjugated molecules are characterized in that they have overlapping π orbitals and that they can assume two or more resonant structures.

It is to be appreciated that the organic layer 114 can be formed via a number of suitable techniques including, for example, a spin-on technique which involves depositing a mixture of the material and a solvent, and then removing the solvent. Another suitable technique is chemical vapor deposition (CVD), including low pressure chemical vapor deposition (LPCVD), plasma enhanced chemical vapor deposition (PECVD), and high density chemical vapor deposition (HDCVD). It will be appreciated that the passive layer 110 can in some instances act as a catalyst when forming the organic layer 114. In this connection, a backbone of a conjugated organic molecule may initially form adjacent the passive layer 110, and grow or assemble away and substantially perpendicular to the passive layer surface. As a result, the backbones of the conjugated organic molecule may be self aligned in a direction that traverses the two electrodes.

The organic material may be cyclic or acyclic. For some cases, such as organic polymers, the organic material self assembles between the electrodes during formation or deposition. Examples of conjugated organic polymers that can be employed for the organic layer 114 include one or more of polyacetylene (cis or trans); polyphenylacetylene (cis or trans); polydiphenylacetylene; polyaniline; poly(p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Additionally, the properties of the organic material can be modified by doping with a suitable dopant (e.g., salt).

The top electrode 120 is formed on the organic layer 114 and/or over the passive layer 110. It is to be appreciated that the top electrode 120 can be formed prior to formation of the organic layer 114 depending on which technique is employed to form the organic layer 114. The top electrode 120 is comprised of a conductive material such as, aluminum, chromium, copper, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar, Monel®, Inconel®, brass, stainless steel, magnesium-silver alloy, and various other alloys. The top electrode 120 can be comprised of nickel, cobalt, chromium, silver, copper, other suitable materials, and/or alloys thereof. Additionally, alloys with copper and alloys with phosphor and boron can also be employed. It is to be appreciated that the conductive material employed for the top electrode can be, but does not have to be, the same as that of the conductive material employed for the bottom electrode.

It is to be appreciated that the thickness of the bottom electrode 108 and the top electrode 120 can vary depending on the implementation and the memory cell being constructed. However, some exemplary thickness ranges include about 0.01 μm or more and about 10 μm or less, about 0.05 μm or more and about 5 μm or less, and/or about 0.1 μm or more and about 1 μm or less.

The organic layer 114 and the passive layer 110 are collectively referred to as a selectively conductive media or a selectively conductive layer. The conductive properties of this media (e.g., conductive, non-conductive, semi-conductive) can be modified in a controlled manner to affect the operation of the memory cell by applying various voltages across the media via the electrodes 108 and 120.

The organic layer 114 has a suitable thickness that depends upon the chosen implementations and/or the memory cell being fabricated. Some suitable exemplary ranges of thickness for the organic polymer layer 114 are about 0.001 μm or more and about 5 μm or less, about 0.01 μm or more and about 2.5 μm or less, and about a thickness of about 0.05 μm or more and about 1 μm or less. Similarly, the passive layer 110 has a suitable thickness that can vary based on the implementation and/or memory cell being fabricated. Some examples of suitable thicknesses for the passive layer 110 are as follows: a thickness of about 2 Å or more and about 0.1 μm or less, a thickness of about 10 Å or more and about 0.01 μm or less, and a thickness of about 50 Å or more and about 0.005 μm or less.

In order to facilitate operation of the organic memory cell 100, the organic layer 114 is generally thicker than the passive layer 110. In one aspect, the thickness of the organic layer is from about 0.1 to about 500 times greater than the thickness of the passive layer. It is appreciated that other suitable ratios can be employed in accordance with the present invention.

The organic memory cell 100, like conventional memory cells, can have two states, a conductive (low impedance or “on”) state or non-conductive (high impedance or “off”) state. However, unlike conventional memory cells, the organic memory cell is able to have/maintain a plurality of states, in contrast to a conventional memory cell that is limited to two states (e.g., off or on). The organic memory cell can employ varying degrees of conductivity to identify additional states. For example, the organic memory cell can have a low impedance state, such as a very highly conductive state (very low impedance state), a highly conductive state (low impedance state), a conductive state (medium level impedance state), and a non-conductive state (high impedance state) thereby enabling the storage of multiple bits of information in a single organic memory cell, such as 2 or more bits of information or 4 or more bits of information (e.g., 4 states providing 2 bits of information, 8 states providing 3 bits of information . . . ).

During typical device operation, electrons flow from the second electrode 120 through the selectively conductive media to the first electrode 108 based on a voltage applied to the electrodes if the organic layer is n-type conductor. Alternately, holes flow from the first electrode 108 to second electrode 120 if the organic layer 114 is p-type conductor, or both electrons and holes flow in the organic layer if it can be both n and p type with proper energy band match with 110 and 120. As such, current flows from the first electrode 108 to the second electrode 120 via the selectively conductive media.

Switching the organic memory cell to a particular state is referred to as programming or writing. Programming is accomplished by applying a particular voltage (e.g., 9 volts, 2 volts, 1 volts, . . . ) across the selectively conductive media via the electrodes 108 and 120. The particular voltage, also referred to as a threshold voltage, varies according to a respective desired state and is generally substantially greater than voltages employed during normal operation. Thus, there is typically a separate threshold voltage that corresponds to respective desired states (e.g., “off”, “on”. . . ). The threshold value varies depending upon a number of factors including the identity of the materials that constitute the organic memory cell, the thickness of the various layers, and the like.

Generally speaking, the presence of an external stimuli such as an applied electric field that exceeds a threshold value (“on” state) permits an applied voltage to write, read, or erase information into/from the organic memory cell; whereas the absence of the external stimuli that exceeds a threshold value (“off” state) prevents an applied voltage to write or erase information into/from the organic memory cell.

To read information from the organic memory cell, a voltage or electric field (e.g., 2 volts, 1 volts, 0.5 volts) is applied via a voltage source. Then, an impedance measurement is performed which, therein determines which operating state the memory cell is in (e.g., high impedance, very low impedance, low impedance, medium impedance, and the like). As stated supra, the impedance relates to, for example, “on” (e.g., 1) or “off” (e.g., 0) for a dual state device or to “00”, “01”, “10”, or “11” for a quad state device. It is appreciated that other numbers of states can provide other binary interpretations. To erase information written into the organic memory cell, a negative voltage or a polarity opposite the polarity of the writing signal that exceeds a threshold value is applied.

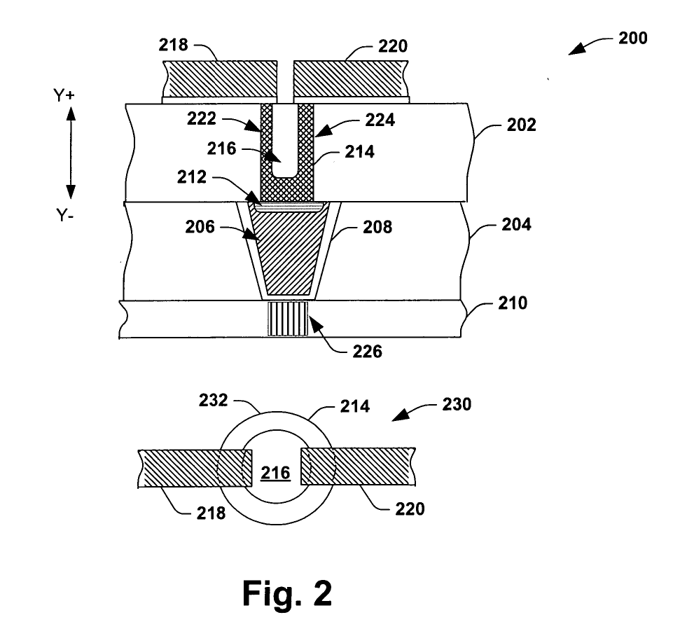

FIG. 2 is a cut away view illustrating another organic memory cell 200, a portion of which can be formed in accordance with one or more aspects of the present invention. The memory cell is a multi-cell memory device. For illustrative purposes, a dual cell structure is described for the memory device 200 although it is to be appreciated that memory structures having more than two cells can be created. Within dielectric layer 204, a lower electrode 206 is formed having an associated barrier layer 208 that mitigates diffusion of the lower electrode 206 into a subsequent layer 210. The lower electrode 206 is a generally conductive material, such as copper, but can also include, for example, any other suitable conductive material such as aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, and the like. Examples of alloys that can be utilized for the conductive material include Hastelloy®, Kovar®, Invar, Monel®, Inconel®, brass, stainless steel, magnesium-silver alloy, and various other alloys.

A passive layer 212 is formed atop the lower electrode 206 in accordance with one or more aspects of the present invention. The passive layer can, for example, be copper sulfide (Cu₂S, CuS) and can be formed on the conductive lower electrode 206 by plasma treatment with a fluorine (F) gas, for example. The plasma treatment alters the makeup of the conductive material comprising the bottom electrode and causes it to have conductivity facilitating properties. The lower electrode 206 and associated passive layer (or layers) 212 cooperate as a common activation or access element for the multi-cell memory device 200.

After the passive layer 212 has been formed, a dielectric layer 202 is added above the layer 204, and organic semiconductor material 214 is formed within the layer 202. Such organic material can be, for example, a polymer including organic polymers, such as one or more of polyacetylene (cis or trans); polyphenylacetylene (cis or trans); polydiphenylacetylene; polyaniline; poly(p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like.

The organic material 214 is partially filled with a dielectric material 216, such as can include, for example, silicon oxide (SiO), silicon dioxide (SiO₂), silicon nitride (Si₃N₄), (SiN), silicon oxynitride (SiOₓN_{y}), fluorinated silicon oxide (SiOₓF_{y}), polysilicon, amorphous silicon, tetraethyorthosilicate (TEOS), phosphosilicate glass (PSG), borophosphosilicate glass (BPSG), any suitable spin-on glass, polyimide(s) or any other suitable insulating material. As illustrated, two conductive electrodes 218 and 220 are formed above the organic material 214, whereby memory cells 222 and 224 are formed in vertical portions (Y+ and Y− directions) of the organic material 214. Thus, if a suitable voltage is applied between electrode 218 and electrode 206, a storage state (e.g., 1, 0, other impedance state) can be stored in (or read from) the memory cell 222, whereas if a suitable voltage is applied between electrode 220 and electrode 206, a storage state can be stored in (or read from) the memory cell 224.

As noted above, multiple electrodes can be formed above the organic material 214 to form more than two memory cells. Moreover, a plurality of such multi-cell memory devices 200 can be manufactured in accordance with an Integrated Circuit (IC) memory device (e.g., 1 Mbit, 2 Mbit, 8 Mbit storage cells, . . . and so forth, constructed as a non-volatile memory IC). In addition, common-word lines such as illustrated at 226 in layer 210 can be provided to store, erase, read, and write a plurality of multi-cell structures in accordance with the present invention (e.g., 8/16 byte/word erase, read, write).

Referring briefly to reference numeral 230 of FIG. 2, a top view illustrates the dual cell structure of the memory device 200. As can be observed from the top of the structure 230, a cylinder shape (or multi-dimension) structure 232 is formed from the combination of organic material 214 and dielectric material 216 described above.

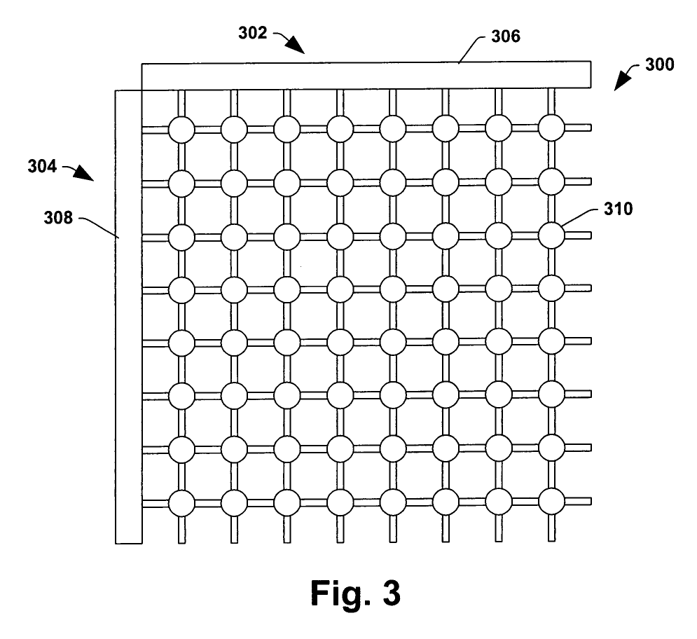

Turning to FIG. 3, an array 300 of memory cells, such as can include memory cells formed in manners(s) described herein, is illustrated. Such an array is generally formed on a silicon based wafer, and includes a plurality of columns 302, referred to as bitlines, and a plurality of rows 304, referred to as wordlines. The intersection of a bitline and a wordline constitutes the address of a particular memory cell. Data can be stored in the memory cells (e.g., as a 0 or a 1) by choosing and sending signals to appropriate columns and rows in the array (e.g., via a column address strobe (CAS) 306 and a row address strobe (RAS) 308, respectively). For example, the state (e.g., a 0 or a 1) of the memory cell indicated at 310 is a function of the 3^{rd} row and 8^{th} column of the array 300. In dynamic random access memory (DRAM), for example, memory cells include transistor-capacitor pairs. To write to a memory cell, a charge can be sent to the appropriate column (e.g., via CAS 306) to activate the respective transistors in the columns, and the state that respective capacitors should take on can be sent to the appropriate columns (e.g., via RAS 308). To read the state of the cells, a sense-amplifier can determine the level of charge on the capacitors. If it is more than 50 percent, it can be read as a 1; otherwise it can be read as a 0. It is to be appreciated that while the array 300 illustrated in FIG. 3 includes 64 memory cells (e.g., 8 rows×8 columns), the present invention has application to any number of memory cells and is not to be limited to any particular configuration, arrangement and/or number of memory cells.

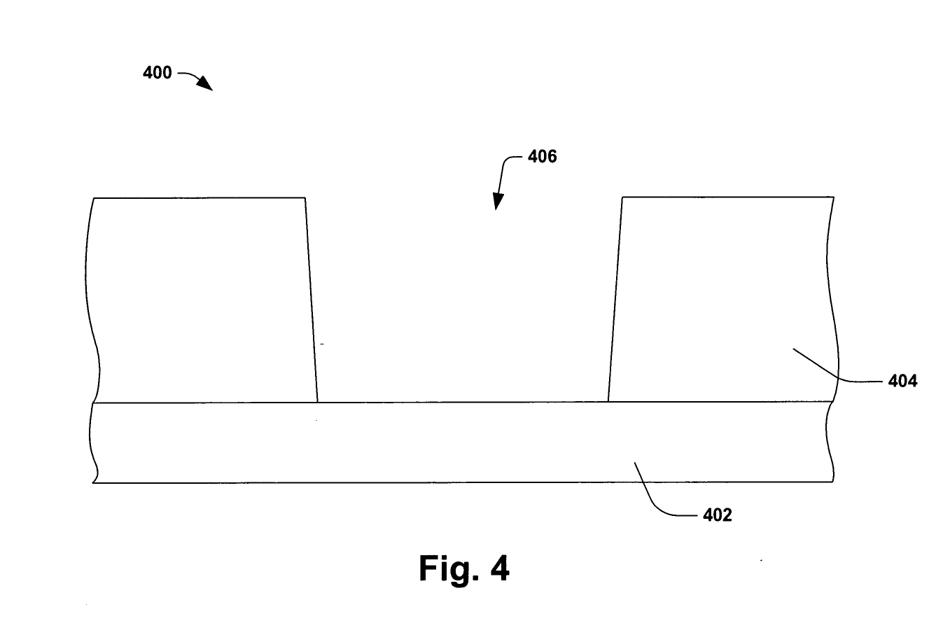

FIG. 4 illustrates a cut away view of layers that can be implemented in forming a memory cell 400. Such a memory cell can, for instance, correspond to the memory cell described above with respect to FIG. 1. The layers include a substrate 402 (e.g., silicon) over which a layer 404 of dielectric or insulating material has been formed. The dielectric layer can be formed in any suitable manner including, for example, via growth, deposition, spin-on and/or sputtering techniques. The dielectric layer 404 has a trench or aperture processed (e.g., etched) therein to accommodate formation of a bottom electrode. The dielectric material 404 can include, for example, silicon oxide (SiO), silicon dioxide (SiO₂), silicon nitride (Si₃N₄), (SiN), silicon oxynitride (SiOₓN_{y}), fluorinated silicon oxide (SiOₓF_{y}), polysilicon, amorphous silicon, tetraethyorthosilicate (TEOS), phosphosilicate glass (PSG), borophosphosilicate glass (BPSG), any suitable spin-on glass, polyimide(s) or any other suitable insulating material.

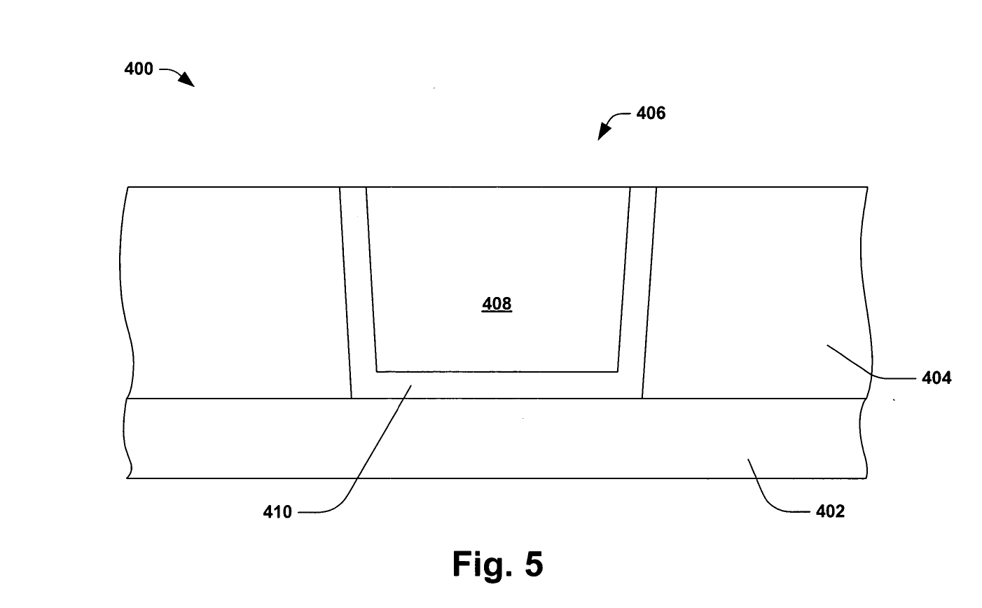

In FIG. 5, the trench 406 is filled with a conductive material 408 in fashioning the bottom electrode. A barrier layer 410 is also formed within the trench, including the bottom and sidewalls to mitigate diffusion of the bottom electrode 408 into the dielectric layer 404 and/or the substrate 402. The conductive material of the bottom electrode 408 can include, for example, copper, aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar, Monel®, Inconel®, brass, stainless steel, magnesium-silver alloy, and various other alloys. The bottom electrode 408 can be formed, for example, by a damascene process whereby the conductive material is deposited (e.g., by sputtering) into the trench to a thickness greater than or equal to that of the surrounding dielectric layer 404. The layers can then be chemically mechanically polished (CMP) to establish a desired level of uniformity and/or thickness. By way of example, some suitable thickness ranges for the conductive layer and surrounding dielectric material include about 0.01 μm or more and about 10 μm or less, about 0.05 μm or more and about 5 μm or less, and/or about 0.1 μm or more and about 1 μm or less.

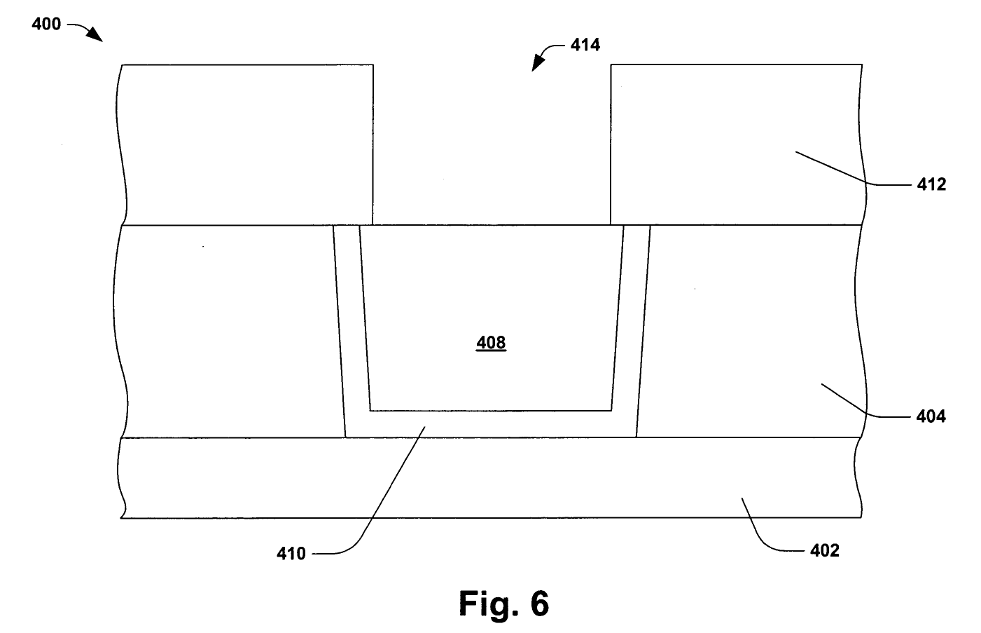

In FIG. 6, a second dielectric layer 412 is formed on the existing dielectric layer 404. The second dielectric layer 412 can be formed in any suitable manner including, for example, via growth, deposition, spin-on and/or sputtering techniques. The second dielectric layer can, but need not, be formed out of the same material constituting the first dielectric layer 404, which includes silicon oxide (SiO), silicon dioxide (SiO₂), silicon nitride (Si₃N₄), (SiN), silicon oxynitride (SiOₓN_{y}), fluorinated silicon oxide (SiOₓF_{y}), polysilicon, amorphous silicon, tetraethyorthosilicate (TEOS), phosphosilicate glass (PSG), borophosphosilicate glass (BPSG), any suitable spin-on glass, polyimide(s) or any other suitable insulating material. It will be appreciated that the dielectric layers 404, 412 can be referred to as inner layer dielectrics (ILD). A trench or via 414 is formed (e.g., etched) into the second dielectric layer to facilitate formation of a passive layer on/out of an upper portion of the conductive material 408 making up the bottom electrode.

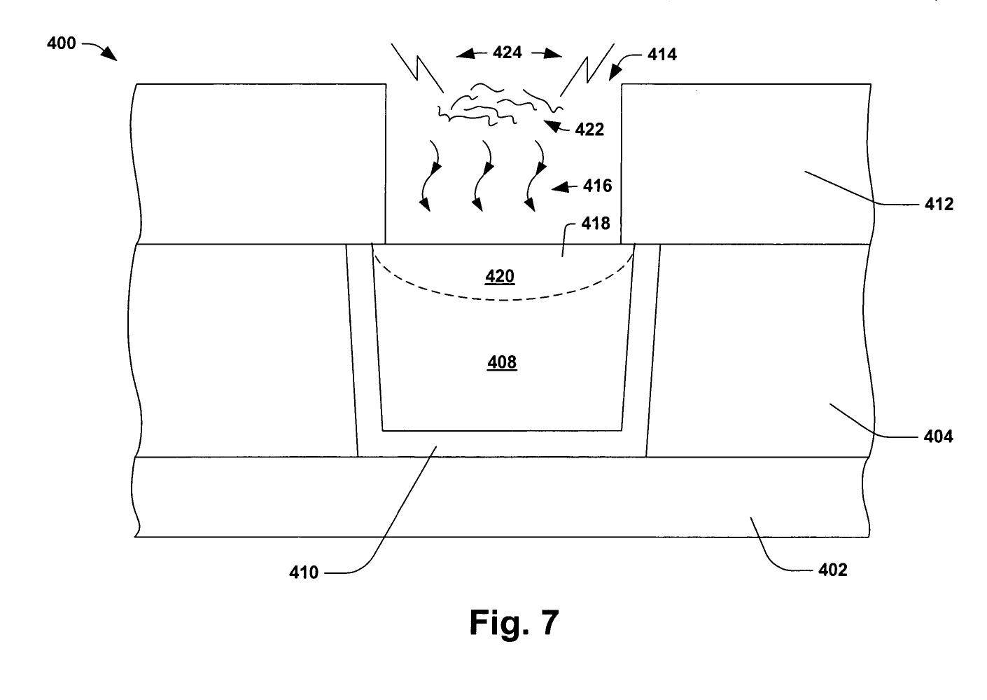

Turning to FIG. 7, some of the bottom electrode 408 is exposed via trench 414 to a plasma treatment. More particularly, a plasma 416 which may be formed from, among other things, fluorine (F), such as CF₄ and/or SF₆, can come into contact with an upper portion 418 of the bottom electrode 408. The plasma 416 interacts with the upper portion 418 and converts the conductive material into a compound having desired conductivity facilitating properties so as to transform the upper portion 418 of the bottom electrode 408 into a passive layer 420 (depicted in phantom), which facilitates conductivity between the bottom electrode 408 and other layers that will subsequently be formed thereon in fashioning the memory cell 400.

By way of example, a gaseous form 422 of SF₆ can be introduced above the bottom electrode 408, which can, at least partially, be formed out of copper (Cu). An rf excitation source 424 can be utilized to excite the gas 422 and develop the fluorine based plasma 416. The plasma 416 can interact with the upper portion 418 to convert the conductive copper into a thin layer of copper sulfide (Cu₂S, CuS) atop the bottom electrode 408. The passive layer 420 can thus be said to be “grown” from the bottom electrode 408. It is to be appreciated that the passive layer 420 can then undergo further processing, such as polishing and/or etching to achieve a desired level of uniformity and/or thickness, for example. Some examples of suitable thicknesses for the passive layer 420 for particular implementations of the memory cell are as follows: a thickness of about 2 Å or more and about 0.1 μm or less, a thickness of about 10 Å or more and about 0.01 μm or less, and a thickness of about 50 Å or more and about 0.005 μm or less. It is to be further appreciated that the plasma treatment can occur before the second dielectric layer 412 is added to the stack. Additionally, the conductivity facilitating passive layer 420 can have, for example, a refractive index from about 2.0 to 2.21, a resistivity of about 5.7×10⁻² Ohm cm and can be transparent with a transmittance of about 60% between 600 and 700 nm. It is noted, however, that the present invention is not to be strictly limited by these parameters as they are merely examples of but some of the many process parameters and properties of the passive layer that can exist according to one or more aspects of the present invention.

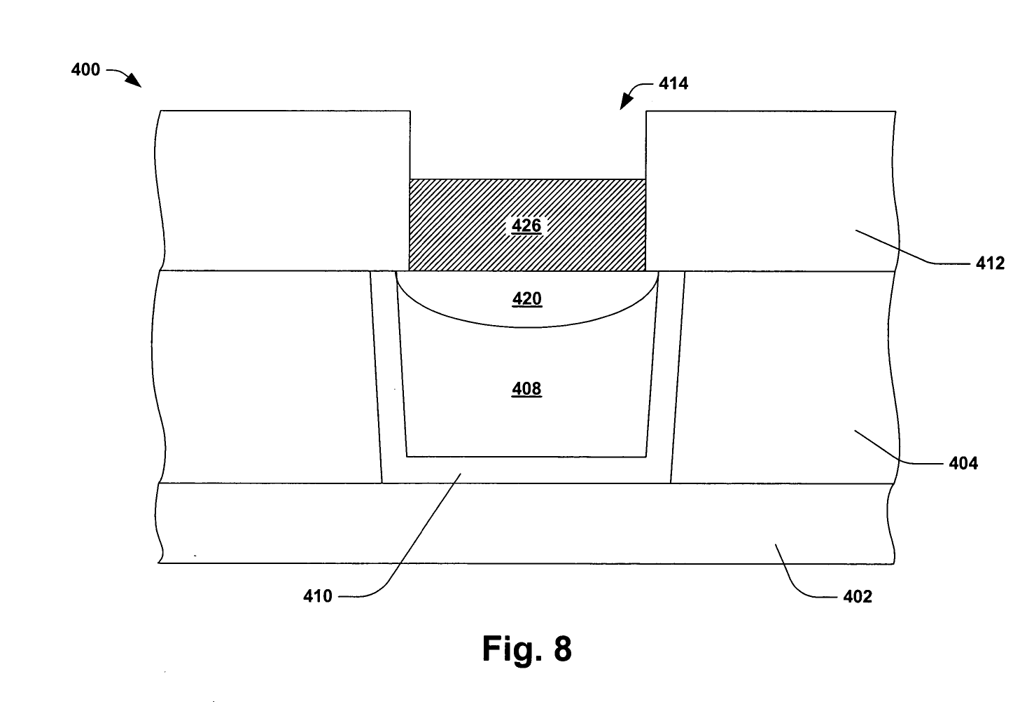

With reference not to FIG. 8, after the top portion 418 of the bottom electrode 408 has been converted to the passive layer 420, an organic layer 426 is formed on the passive layer 420. The organic layer can be formed in any suitable manner. One technique that can be utilized to form the organic layer 426 is a spin-coating technique which involves depositing a mixture of material that makes up the organic layer and then quickly rotating the wafer to evenly distribute the material across the wafer, including into the aperture 414. Alternatively, or in addition, sputtering, growth and/or deposition techniques can be implemented to form the organic layer 426 including, for example, physical vapor deposition (PVD), chemical vapor deposition (CVD), low pressure chemical vapor deposition (LPCVD), plasma enhanced chemical vapor deposition (PECVD), high density chemical vapor deposition (HDCVD), rapid thermal chemical vapor deposition (RTCVD), metal organic chemical vapor deposition (MOCVD) and pulsed laser deposition (PLD). Excess organic material can be removed from the dielectric layer 414 by way of chemical mechanical polishing (CMP) or other suitable means. The organic layer 426 can also undergo further processing (e.g., etching) to achieve a desired thickness and/or level of uniformity.

The organic layer 426 can include organic material that can be cyclic or acyclic. Examples of conjugated organic polymers that can be employed for the organic layer 426 include one or more of polyacetylene (cis or trans); polyphenylacetylene (cis or trans); polydiphenylacetylene; polyaniline; poly(p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Some exemplary ranges of thickness for the organic layer 426 for particular implementations of the memory cell include about 0.001 μm or more and about 5 μm or less, about 0.01 μm or more and about 2.5 μm or less, and about a thickness of about 0.05 μm or more and about 1 μm or less. In order to facilitate operation of the organic memory cell 400, the organic layer 426 is generally thicker than the passive layer 420. In one aspect, the thickness of the organic layer is from about 0.1 to about 500 times greater than the thickness of the passive layer. It is appreciated that other suitable ratios can be employed in accordance with the present invention.

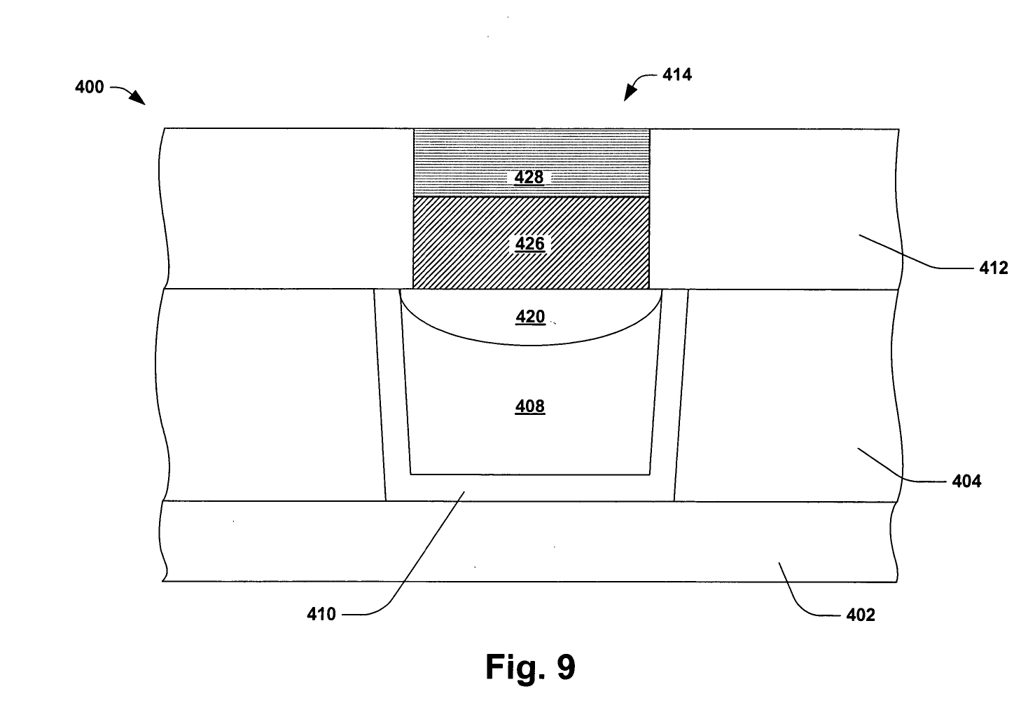

FIG. 9 illustrates the completed memory cell with a top electrode 428 formed over the organic layer 426. The top electrode 428 includes a conductive material, such as, aluminum, chromium, copper, germanium, gold, magnesium, manganese, indium, iron, nickel, palladium, platinum, silver, titanium, zinc, alloys thereof, indium-tin oxide, polysilicon, doped amorphous silicon, metal suicides, and the like. Exemplary alloys that can be utilized for the conductive material include Hastelloy®, Kovar®, Invar, Monel®, Inconel®, brass, stainless steel, magnesium-silver alloy, and various other alloys. It is to be appreciated that the conductive material employed for the top electrode can be, but does not have to be, the same as that of the conductive material employed for the bottom electrode 408.

The top electrode 428 can be formed in any suitable manner including, for example, via growth, deposition, spin-on and/or sputtering techniques. Excess conductive material can be removed from the dielectric layer 412 by way of chemical mechanical polishing techniques, for example. Additional processing (e.g., etching and/or polishing) can also be performed on the top electrode 428 to achieve a desired level of uniformity and/or thickness, for example. Some exemplary thickness ranges for the top electrode 428 include about 0.01 μm or more and about 10 μm or less, about 0.05 μm or more and about 5 μm or less, and/or about 0.1 μm or more and about 1 μm or less.

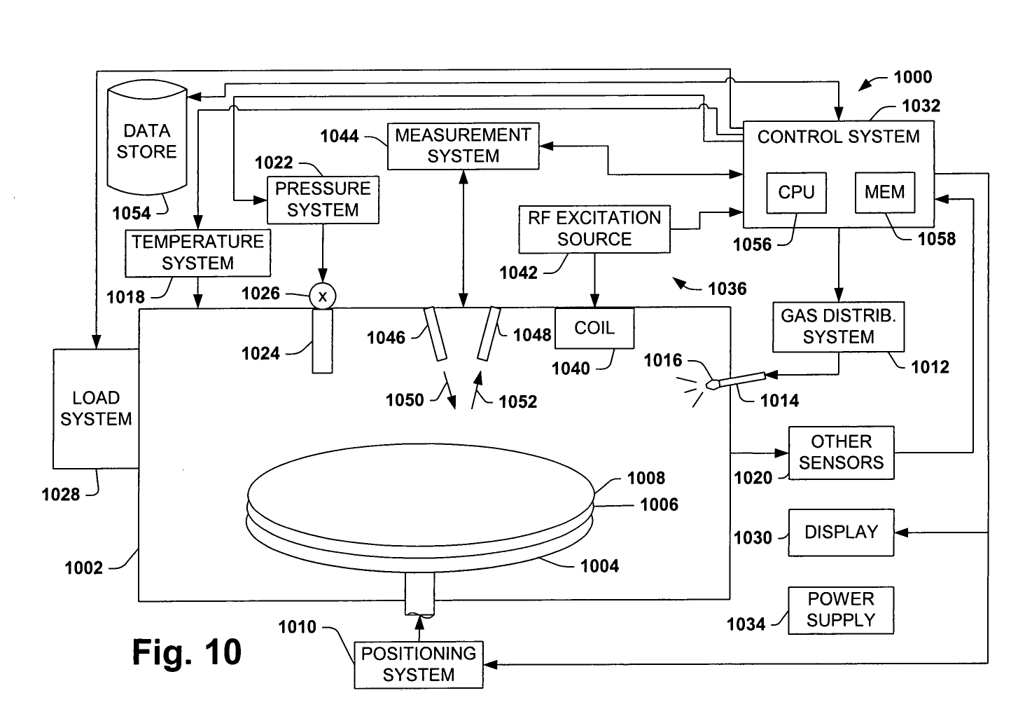

FIG. 10 is a schematic block diagram illustrating a system 1000 for forming a passive layer (e.g., copper sulfide (Cu₂S, CuS)) atop a layer of conductive material (e.g., copper) in accordance with one or more aspects of the present invention, and more particularly via a plasma treatment which transforms an upper portion of the conductive material so as to have conductivity facilitating properties. It will be appreciated that formation rates may vary in response to factors including, but not limited to, gas compositions and/or concentrations, excitation voltages, temperatures and/or pressures. The formation described herein can be utilized as part of a semiconductor fabrication process wherein one or more memory cells are produced on a wafer.

The system 1000 includes a chamber 1002 defined by a housing having a plurality of walls. The chamber 1002 includes a support, such as may include a stage 1004 (or chuck) operative to support a wafer 1006 which includes conductive material 1008 out of which one or more passive layers can be selectively formed as part of producing one or more memory cells. It will be appreciated that while a continuous layer 1008 of conductive material generally appears to be depicted in FIG. 10, the wafer may include one or more formations of dielectric material(s) having one or more trenches formed therein which can contain deposits of conductive material selectively formed therein, and which leaves (an upper portion of) the deposits of conductive material exposed for subsequent processing (e.g., as illustrated in FIGS. 4-9).

A positioning system 1010 is operatively connected to the support 1004 for selectively maneuvering the wafer 1006 into desired positions within the chamber 1002. It is to be appreciated that any suitable positioning system may be employed in accordance with one or more aspects of the present invention. It is to be further appreciated that the conductive material can be copper as well as any other suitable conductive material such as aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, and the like. Examples of alloys that can be utilized for the conductive material include Hastelloy®, Kovar®, Invar, Monel®, Inconel®, brass, stainless steel, magnesium-silver alloy, and various other alloys.

A gas distribution system 1012 is operatively coupled to the chamber 1002 for selectively providing gaseous chemicals into the chamber at various rates, volumes, concentrations, etc. base upon, among other things, the thickness of the passive layer(s) to be formed, the composition of the passive layer(s) to be formed, the pressure within the chamber, the temperature within the chamber and/or the size of the chamber, for example. The gas distribution system 1012 includes one or more sources of gaseous medium (a vapor) of one or more chemical(s), such as fluorine (F) based gases (e.g., CF₄ and/or SH₆) for injection into the chamber. In the example illustrated, the gases are provided into the chamber through a conduit 1014 that terminates in a nozzle 1016. While, for purposes of brevity, a single nozzle 1016 is shown in FIG. 10, it is to be appreciated that more than one nozzle or other gas delivery mechanisms may be utilized to provide gas into the chamber 1002 at various mixtures and/or concentrations in accordance with one or more aspects of the present invention. For example, a shower head type gas delivery mechanism can be implemented to more evenly provide chemicals into the chamber above the wafer 1006, which can facilitate more uniform chemical reactions in conductive materials selectively deposited into and exposed by trenches formed in dielectric material(s) spread across the wafer.

A temperature system 1018 also is provided for selectively regulating the temperature within the chamber 1002. For example, the system 1018 may be a diffusion type system (e.g., a horizontal or vertical furnace) operable to diffusion heat into the chamber 1002. The temperature system 1018 may implement its own temperature control process or such control may be implemented as part of other sensors 1020 operatively associated with the etching chamber 1002. A pressure system 1022 is also included in the system to selectively regulate the pressure within the chamber. The pressure system 1022 may include, for example, one or more vent conduits 1024 having valves 1026 that may be controllably opened and/or closed to varying degrees to assist with selectively adapting the pressure within the chamber 1002.

The system 1000 can also include a load system 1028 operatively connected to the chamber 1002 for loading and unloading wafers into and out of the etching chamber. The load system 1028 typically is automated to load and unload the wafers into the chamber at a controlled rate. The system further may include a display 1030 operatively coupled to a control system 1032 for displaying a representation (e.g., graphical and/or textual) of one or more operating parameters (e.g., temperature within the chamber, pressure within the chamber, thickness of passive layer, composition of passive layer, conductivity of passive layer, rate of conversion of conductive material to conductivity facilitating passive layer).

A power supply 1034 is included to provide operating power to components of the system 1000. Any suitable power supply (e.g., battery, line power) suitable for implementation with the present invention can be utilized. An excitation system 1036 is operatively associated with the chamber 1002. The system 1036 includes a coil 1040 and an RF excitation (e.g., voltage) source 1042 wherein the coil 1040 is excited by the RF excitation source 1042 which in turn electrically excites one or more of the fluorine (F) based gases within the chamber to generate a plasma which interacts with exposed portions of conductive material (e.g., copper) deposited into trenches formed within dielectric materials spread across the wafer. The depositions of conductive material can correspond to bottom electrodes of organic memory cells, and the plasma can facilitate conversion of the exposed upper portions of the conductive material into conductivity facilitating materials, such as copper sulfide, to establish passive layers in fashioning organic memory cells.

The system can also include a measurement system 1044 for in-situ monitoring of processing within the chamber, such as, for example, thickness of passive layer(s) being out of upper portions of depositions of conductive material. The monitoring system 1044 can be a standalone component and/or can also be distributed between two or more cooperating devices and/or processes. Similarly, the monitoring system 1044 can reside in one physical or logical device (e.g., computer, process) and/or be distributed between two or more physical or logical devices. The measurement system 1044 includes one or more non-destructive measurement components, such as may utilize optical interference, scatterometry, IR spectroscopy, ellipsometry, scanning electron microscopy, synchrotron and/or x-ray diffraction techniques, for example. The measurement system includes a beam source 1046 and detector 1048. It is to be appreciated that while one beam source 1046 and one beam detector 1048 are shown in the example illustrated, more than one of these components may be included to measure passive layer attributes and/or other processing conditions at various locations on the wafer.

The source portion 1046 provides one or more beam(s) 1050 (e.g., of light from a frequency stabilized laser, laser diode or helium neon (HeNe) gas laser) toward the surface of the wafer 1006. The beam 1020 interacts with surface conditions, such as density, composition, etc. of passive layer(s) being formed and is altered thereby (e.g., reflected, refracted, diffracted). The altered beam(s) 1052 are received at the detector portion 1048 of the measurement system 1044 and have beam properties (e.g., magnitude, angle, phase, polarization), which can be examined relative to that of the incident beam(s) 1050 to determine an indication of one or more properties of the passive layer(s) being formed (e.g., thickness, chemical species, conductivity). A plurality of incident beams from one or more sources directed at different spaced apart locations may be employed, for example, to yield corresponding measurements of passive layer properties at these locations substantially concurrently during the process. The concurrent measurements, in turn, may provide an indication of processing uniformity and may be useful in controlling the process to efficiently and economically achieve desired results.

With respect to optical interference, for example, the intensity of light over a selected wavelength varies as a function of surface properties (e.g., thickness, chemical composition). For spectroscopic ellipsometry, thickness varies based on the state of polarization of reflected light, which is functionally related to the index of refraction of the material reflecting the beam 1052.

Using a scatterometry technique, for example, desired information concerning thickness and/or chemical composition can be extracted by comparing the phase and/or intensity (magnitude) of the light directed onto the surface with phase and/or intensity signals of a complex reflected and/or diffracted light resulting from the incident light reflecting from the surface upon which the incident light was directed. The intensity and/or the phase of the reflected and/or diffracted light will change based on properties (e.g., thickness, chemical species, conductivity, composition) of the surfaces upon which the light is directed.

Substantially unique intensity/phase signatures can be developed from the complex reflected and/or diffracted light. The measurement system 1044 provides information indicative of the measured properties to the control system 1032. Such information may be the raw phase and intensity information. Alternatively or additionally, the measurement system 1044 may be designed to derive an indication of thickness, for example, based on the measured optical properties and provide the control system 1032 with a signal indicative of the measured film thickness according to the detected optical properties. The phase and intensity of the reflected light can be measured and plotted to assist with such determinations, such as, for example, by way of derived curve comparisons.

In order to determine thickness, for example, measured signal characteristics may be compared with a signal (signature) library of intensity/phase signatures to determine properties of the deposited by-products. Such substantially unique phase/intensity signatures are produced by light reflected from and/or refracted by different surfaces due, at least in part, to the complex index of refraction of the surface onto which the light is directed. The complex index of refraction (N) can be computed by examining the index of refraction (n) of the surface and an extinction coefficient (k). One such computation of the complex index of refraction can be described by the equation:
N=n−jk, Eq. 1

where j is an imaginary number.

The signal (signature) library can be constructed from observed intensity/phase signatures and/or signatures generated by modeling and simulation. By way of illustration, when exposed to a first incident light of known intensity, wavelength and phase, a first feature on a surface can generate a first phase/intensity signature. Similarly, when exposed to the first incident light of known intensity, wavelength and phase, a second feature on a surface can generate a second phase/intensity signature. For example, a particular type of material having a first thickness may generate a first signature while the same type of material having a different thickness may generate a second signature, which is different from the first signature. Observed signatures can be combined with simulated and modeled signatures to form the signal (signature) library. Simulation and modeling can be employed to produce signatures against which measured phase/intensity signatures can be matched. Simulation, modeling and observed signatures can, for example, be stored in a signal (signature) library or data store 1054 containing, for example, thousands of phase/intensity signatures. Such a data store 1054 can store data in data structures including, but not limited to one or more lists, arrays, tables, databases, stacks, heaps, linked lists and data cubes. Thus, when the phase/intensity signals are received from scatterometry detecting components, the phase/intensity signals can be pattern matched, for example, to the library of signals to determine whether the signals correspond to a stored signature. Interpolation between the two closest matching signatures further may be employed to discern a more accurate indication of thickness and/or composition from the signatures in the signature library. Alternatively, artificial intelligence techniques may be employed to calculate desired parameters based on the detected optical properties.

It is to be appreciated that the beam 1050 illustrated in FIG. 10 may be oriented at any angle relative to the surfaces of the wafer with a corresponding detector appropriately positioned for receiving the reflected beam. In addition, more than one beam may be directed toward different locations to measure the respective thickness at such different locations to facilitate a measurement of uniformity or thickness. The thickness of the material is thus determined based upon the optical properties (e.g., n and k) of emitted and reflected beams 1052.

One or more other sensors 1020 can also be included to monitor and/or measure selected aspects related to the processing occurring within the chamber (e.g., temperature within the chamber, pressure within the chamber, volume and/or flow rate of gasses being distributed into the chamber). These sensors 1020 can provide respective signals to the control system 1032 indicative of the aspects sensed thereby. The various other subsystems 1012, 1018, 1022, 1036 can further provide respective signals to the control system 1032 indicative of operating conditions associated with the respective systems (e.g., degree that vent valve(s) are open, time period(s) that particular valve(s) have been closed). Considering the signals and information received from the measurement system, 1044 other sensors 1020 and subsystems 1012, 1018, 1022, 1036, the control system 1032 can discern whether the process is proceeding as planned. If not, the control system can adapt the process by formulating and selectively providing appropriate control signals to the associated systems 1010, 1012, 1018, 1022, 1028, 1036, to adjust one or more of the systems (e.g., to increase the volume of fluorine (F) based gases provided into the chamber).

The control system 1032 can include, for example, a processor 1056, such as a microprocessor or CPU, coupled to a memory 1058. The processor 1056 receives measured data from the measuring system 1044 and corresponding other data from the other sensors 1020 and subsystems 1012, 1018, 1022, 1036. The control system 1032 can be configured in any suitable manner to control and operate the various components within the system 1000 in order to carry out the various functions described herein. The processor 1056 can be any of a plurality of processors, and the manner in which the processor 1056 can be programmed to carry out the functions relating to the present invention will be readily apparent to those having ordinary skill in the art based on the description provided herein.

The memory 1058 included within the control system 1032 serves to store, among other things, program code executed by the processor 1056 for carrying out operating functions of the system as described herein. The memory 1058 may include read only memory (ROM) and random access memory (RAM). The ROM contains among other code the Basic Input-Output System (BIOS) which controls the basic hardware operations of the system 1000. The RAM is the main memory into which the operating system and application programs are loaded. The memory 1058 also serves as a storage medium for temporarily storing information such as, for example, thickness tables, chemical composition tables, temperature tables, pressure tables and algorithms that may be employed in carrying out one or more aspects of the present invention. The memory 1058 can also serve as the data store 1054 and can hold patterns against which observed data can be compared as well as other data that may be employed in carrying out the present invention. For mass data storage, the memory 1058 may include a hard disk drive.

As a result, the system 1000 provides for monitoring aspects associated with the processing occurring within the chamber, such as the thickness, composition and/or conductivity of passive layer(s) being deposited, for example. The control system 1032 may implement feedback and/or feed forward process control in response to the monitoring so as to form conductivity facilitating material, such as copper sulfide, in an efficient and cost effective manner. It will be appreciated that many of the components of the system 1000 including the data store can, for example, reside in one physical or logical device (e.g., computer, process) and/or may be distributed between two or more physical or logical devices (e.g., disk drives, tape drives, memory units). Measuring thickness of material being formed in-situ and adapting processing in response thereto facilitates forming the passive layer(s) at a desired rate, to a desired thickness, with a desired chemical makeup and/or with other desired properties. The passive layer(s) can, for example, have a refractive index from about 2.0 to 2.21, a resistivity of about 5.7×10⁻² Ohm cm and can be transparent with a transmittance of about 60% between 600 and 700 nm. In-situ measurement and feedback and/or feed-forward control, at least, enhances product yield and improves resulting device performance, among other things, over conventional systems.

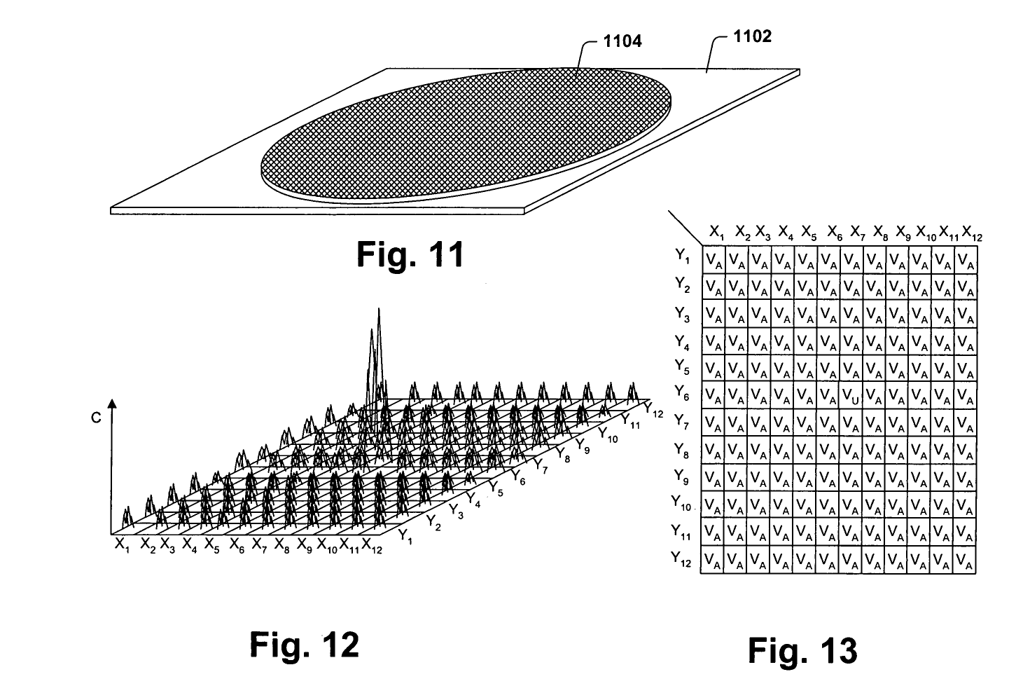

Turning now to FIGS. 11-13 a chuck 1102 is shown in perspective supporting a wafer 1104 whereupon one or more passive layers (e.g., copper sulfide) can be formed via a fluorine based plasma treatment that transforms upper portions of conductive material so as to have conductivity facilitating properties in the manufacture one or more organic memory cells. The wafer 1104 may be logically partitioned into a grid pattern as shown in FIG. 12 to facilitate monitoring the wafer as it matriculates through a fabrication process. Each grid block (XY) of the grid pattern corresponds to a particular portion of the wafer 1104, and each grid block may have one or more memory cells associated with that grid block. Portions can be individually monitored with one or more innocuous techniques such as, for example, optical interference, scatterometry, IR spectroscopy, ellipsometry, scanning electron microscopy, synchrotron and/or x-ray diffraction for properties including, but not limited to, thickness of passive layer(s) formed, composition of passive layer(s), etc. This may facilitate selectively determining to what extent, if any, fabrication adjustments are necessary to mitigate problem areas and achieve desired results.

In FIG. 12, respective plots are illustrated for measurements taken at portions of a wafer 1104 corresponding to grid mapped locations of the wafer (X₁Y₁ . . . X₁₂, Y₁₂). The plots can, for example, be signatures indicating whether copper sulfide is forming at an acceptable rate and/or has been formed to a desired thickness. Given the values depicted in FIG. 12, it may be determined that an undesirable condition exists at one or more locations on the wafer 1104. For instance, the measurement at coordinate X₇Y₆ yields a plot that is substantially higher than the respective measurements of the other portions XY. This can indicate, for example, that copper sulfide is accumulating too fast at this location. As such, fabrication components and/or operating parameters associated therewith can be adjusted accordingly to mitigate this condition. For example, the degree that a vent valve is opened can be reduced so that the volume and/or rate of fluorine bases gases added to the process can be restricted. It is to be appreciated that although FIG. 12 illustrates the wafer 1104 being mapped (partitioned) into 144 grid block portions, the wafer 1104 may be mapped with any suitable number of portions to effect desired monitoring and control.

FIG. 13 illustrates a table of acceptable and unacceptable signature values. As can be seen, all the grid blocks, except grid block X₇Y₆, have measurement values corresponding to an acceptable value (V_{A}), while grid block X₇Y₆ has an undesired value (V_{U}). Thus, it has been determined that an undesirable condition exists at the portion of the wafer 1104 mapped by grid block X₇Y₆. Accordingly, fabrication process components and parameters may be adjusted as described herein to adapt the fabrication process accordingly to mitigate the occurrence or persistence of this condition.

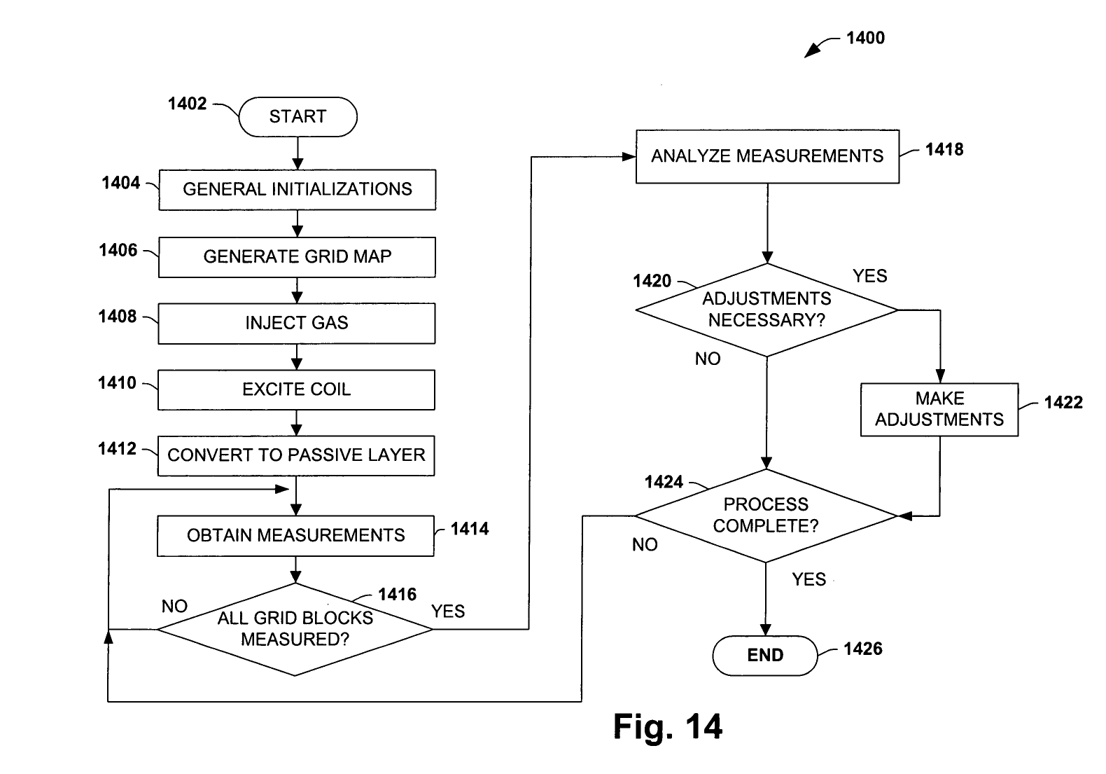

In view of what has been shown and described above, a methodology, which may be implemented in accordance with one or more aspects of the present invention, will be better appreciated with reference to the flow diagram of FIG. 14. While, for purposes of simplicity of explanation, the methodology is shown and described as a series of function blocks, it is to be understood and appreciated that the present invention is not limited by the order of the blocks, as some blocks may, in accordance with the present invention, occur in different orders and/or concurrently with other blocks from that shown and described herein. Moreover, not all illustrated blocks may be required to implement a methodology in accordance with one or more aspects of the present invention. It is to be appreciated that the various blocks may be implemented via software, hardware a combination thereof or any other suitable means (e.g., device, system, process, component) for carrying out the functionality associated with the blocks. It is also to be appreciated that the blocks are merely to illustrate certain aspects of the present invention in a simplified form and that these aspects may be illustrated via a lesser and/or greater number of blocks.

Turning to FIG. 14, a flow diagram illustrates a methodology 1400 for forming a passive layer, such as copper sulfide (Cu₂S, CuS), having conductivity facilitating properties out of an upper portion of conductive material (e.g., copper) deposited on a wafer in accordance with one or more aspects of the present invention. The formation can be part of a process for forming one or more memory cells on the wafer via plasma treatment utilizing fluorine (F) based gases in a deposition chamber. After startup at 1402, general initializations are performed at 1404. Such initializations can include, but are not limited to, establishing pointers, allocating memory, setting variables, establishing communication channels and/or instantiating one or more objects.

At 1406, a grid map comprising one or more grid blocks “XY” is generated on the wafer which is located within the chamber. Such grid blocks may correspond to locations on the wafer where one or more memory cells can be formed, for example. Then, at 1408, a fluorine (F) based gas, such as CF₄ and/or SF₆, for example, is injected into the chamber. It will be appreciated that other ingredients can also be added into the chamber. After the fluorine based gas has been introduced into the chamber, an RF source (e.g., a voltage) excites a coil located within the chamber at 1410. The coil in turn excites the fluorine based gas within the chamber to generate plasma. At 1412, the plasma interacts with upper portions of conductive material exposed through trenches formed in one or more dielectric materials spread across the wafer. The plasma converts the exposed portions of the conductive material into a material, such as copper sulfide, having conductivity facilitating properties, and thus facilitates the formation of a passive layer in fashioning an organic memory cell.

At 1414, as the process progresses, measurements are taken at the grid mapped locations with one or more non-destructive measurement techniques, such as may include, for example, optical interference, scatterometry, IR spectroscopy, ellipsometry, scanning electron microscopy, synchrotron and/or x-ray diffraction. For example, the thickness of a passive layer being formed can be monitored at the respective grid mapped locations. At 1416, a determination is made as to whether measurements have been taken at all (or a sufficient number) of grid mapped locations. If the determination at 1416 is NO, then the methodology returns to 1414 so that additional measurements can be made. At 1418, the measurements are analyzed (e.g., via a comparison of signatures generated from the measurements to stored signature values). For example, measurements of copper sulfide thickness can be compared to acceptable values to determine if the fabrication process is progressing as planned. Measured values can, for example, can be compared to acceptable values to determine if, for instance, the conductivity facilitating material is being deposited too quickly, too slowly, and/or at appropriate locations.

At 1420, a determination is made as to whether the analysis yields an indication that the process should be adjusted (e.g., an undesired value (V_{U}) is encountered). If the determination at 1420 is NO, indicating that no adjustments are necessary, then the methodology proceeds to 1424 where a determination is made as to whether the process is over (e.g., has copper sulfide been formed to a desired thickness, concentration, density, etc. at all desired locations). If the determination at 1424 is NO, then the methodology returns to 1414 to take additional measurements while processing continues. If the determination at 1424 is YES, indicating that processing is over, then the methodology advances to 1426 and ends. If, at 1420, the determination is YES, indicating that adjustments are necessary, then at 1422, one or more fabrications components and/or operating parameters associated therewith can be selectively adjusted as described herein to adapt the process accordingly. For example, if copper sulfide is accumulating too quickly, sophisticated modeling techniques can be employed to determine which of one or more vent valves that allow gaseous fluorine into the chamber should be closed for respective periods of time and/or should be allowed to remain open, but to lesser degrees. After adjustments have been made at 1422, the methodology proceeds to 1424 to see if the process is over. As mentioned above, events can occur in orders different from that depicted in FIG. 14. For example, measurements taken, as at 1414, can be analyzed, as at 1418, prior to determining whether measurements have been taken at all grid mapped locations, as at 1416.

It will be appreciated that a passive layer having conductivity facilitating properties (e.g., CuS) employed in polymer memory cells plays an important role. Its presence significantly improves the conductivity of the organic layer. This characteristic is at least partially a function of the following: charge carrier generated by CuS, build up of a charge depletion layer, charge carrier distribution, and memory loss due to charge carrier redistribution after reversing electric field. The discussion infra describes and illustrates charge carrier concentration and behavior.

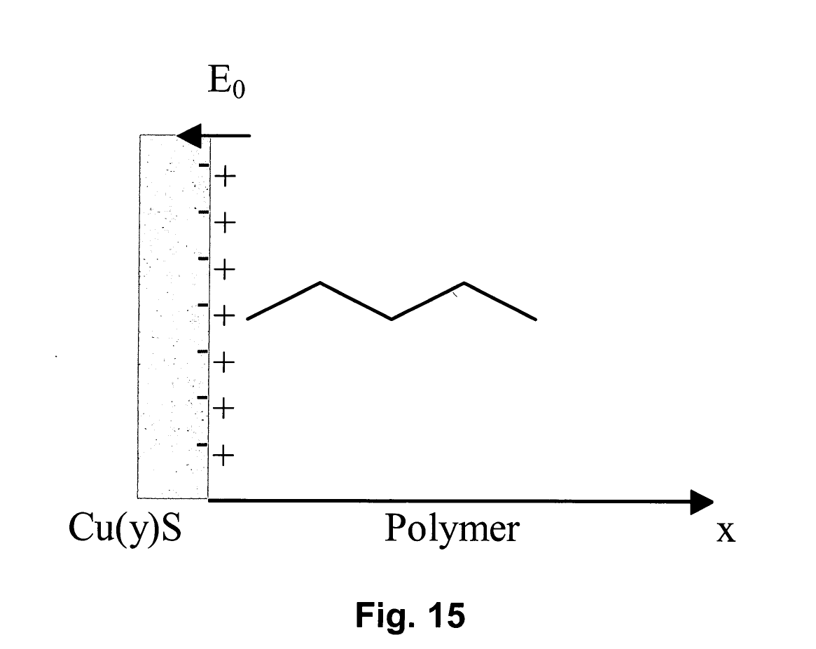

In the following example, a conductive polymer is implemented, and CuS is utilized a conductivity facilitating material. With respect to charge carrier generation, the copper in CuS is at its highest oxidation state Cu(II). It has relatively strong capability to gain electrons from a contacting polymer and yields the following equation:
Cu(II)S+Polymer→Cu(I)S⁻+Polymer⁺ (1)
The consequence is that an intrinsic field is produced due to the charges accumulated on the interface between CuS and polymer. This is shown in FIG. 15, which is a graph depicting the effect of an intrinsic electric field on an interface between Cu(y)S and a polymer is provided. The oxidized polymer (Polymer⁺) is the charge carrier when external field is applied. The conductivity of polymer is determined by its concentration and its mobility.
σ=qpμ (2)

Where q is the charge of the carrier, p is carrier concentration and μ is the mobility.

Referring now to the charge depletion layer, employing a similar concept as applied with respect to semiconductors, a potential function can be expressed as:
V(x)=qNₚ(dₚx−x²/2)/∈ (3)

where Nₚ is the average concentration of charge carrier, ∈ is the dielectric constant of the polymer, and dₚ is the width of the charge depletion. Nₚ can be obtained by employing the following equation:

$${d}_{p} = {[ \frac{2 ɛ ( {V}_{b} \pm V )}{{qN}_{p}} ]}^{1 / 2} \qquad ( 4 )$$

where V is the external field voltage applied. For forward voltage, it is “−” sign. For the reverse voltage, it is “+” sign.
The voltage function of Eq. (3) can be approximated to simplify the derivation.

With respect to charge carrier distribution, like p-doping of a semiconductor, two processes typically take place in the electric field. This flux can be expressed as:

$$J = - qD \frac{ⅆ p}{ⅆ x} + q μ pE \qquad ( 5 )$$

where D is diffusion constant of the charge carrier, and E is the electric field at x. If there is no current, the carrier distribution is:
p(x)=p(0)exp([(V(0)−V(x))/Vt]) (6)
where p(0) is the concentration, V(0) is voltage at the interface respectively, and Vₜ=kT/q.

When forward voltage is so large that the current flux J>0, the analytical equation can be derived for steady state flow with some assumption for the voltage distribution in the cell. Overall, under forward voltage, the charge distribution p(x) is an increase function of x. When reverse voltage is applied, V(x)>V₀, the charge concentration is a decrease function of x.

The final characteristic, retention time, refers to the fact that a forward voltage produces more charge carrier and the charge carrier accumulates more on the other end of the passive (CuS) layer (away from the polymer). However, this charge carrier concentration will be set back once the voltage is removed, which includes two processes: charge carrier diffusion toward the CuS layer and charge carrier recombination on the interface.

Fick's Law can describe the 1st process, charge carrier diffusion toward the CuS layer.

The charge carrier recombination can be described as follows:
Cu(I)S⁻+Polymer⁺→Cu(II)S+Polymer (7)

The retention time is the time required to redistribute the charge carrier to the original state. It is likely that the reaction rate is relatively faster than diffusion rate. Therefore, the retention time can be substantially determined by the diffusion process only.

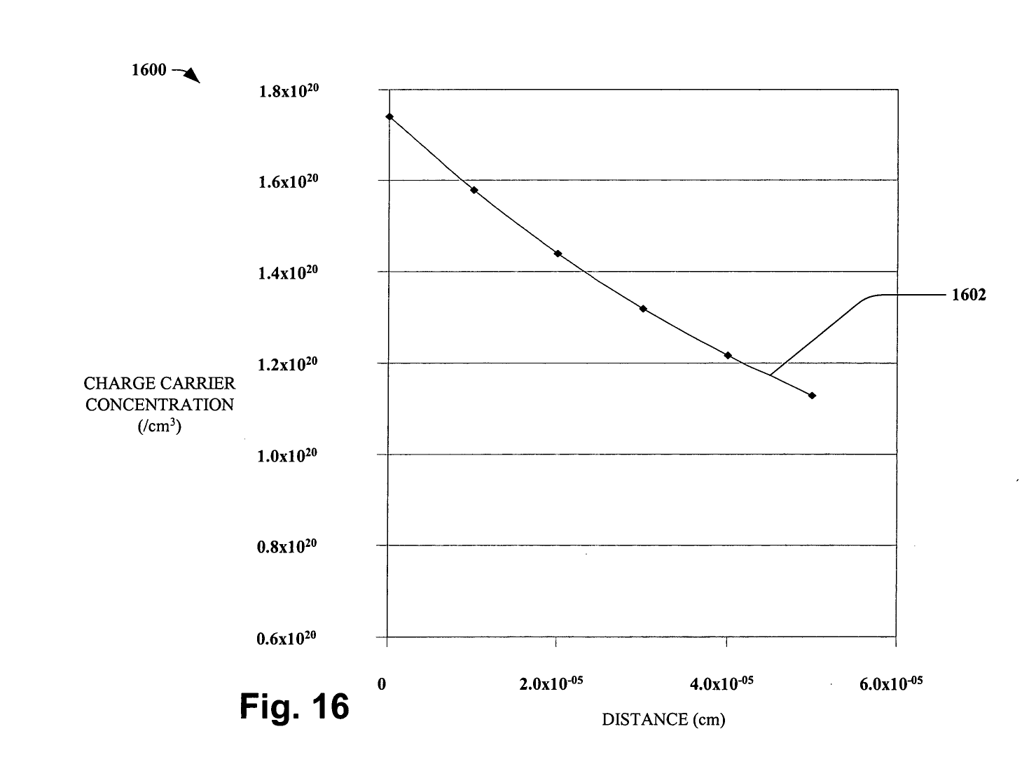

An exemplary memory cell is considered herein with respect to the equations 1-9 discussed supra and illustrated in FIG. 16-21. The exemplary cell is considered with parameters intrinsic voltage V_{b}=0.02V, equilibrium constant K_{eq}=2.17×10⁻⁴, concentration of CuS and Polymer at interface [Polymer]₀=[CuS]₀=10²³/cm³, polymer thickness d=5×10⁻⁵ cm (0.5 um), and CuS thickness d_{Cus}=5×10⁻⁷ cm (0.005 um). Six typical cases are calculated to illustrate electrical operation of an organic memory cell in accordance with an aspect of the present invention.

FIG. 16 depicts a graph 1600 of charge carrier distribution 1602 of the exemplary memory cell as a function of distance from the CuS and organic polymer interface in accordance with an aspect of the invention. The charge carrier concentration 1602 is shown as being a decreasing function of distance (x) from the interface. This graph 1600 assumes an external voltage V=0 and a current J=0. The charge carrier concentration 1602 is derived utilizing Eq. 6 with a constant field assumption. However, the points shown are independent of the constant field assumption.

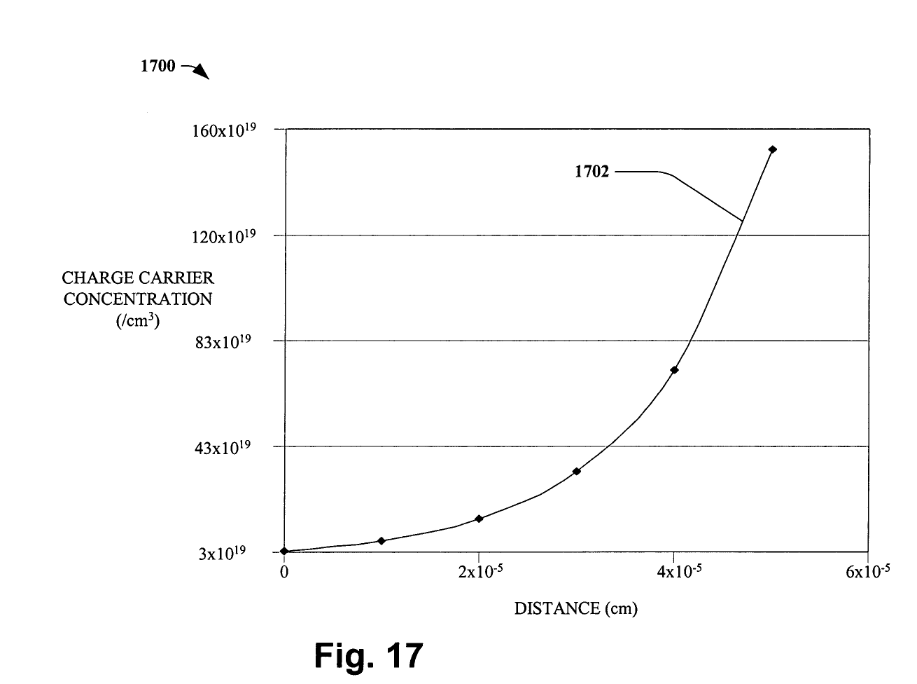

Turning now to FIG. 17, another graph 1700 illustrating charge carrier distribution 1702 for the exemplary organic memory cell is depicted in accordance with an aspect of the present invention. For this graph 1700, parameters are set as follows: forward voltage=0.12V and current flux J=0. The CuS end has a higher voltage than the other end (organic polymer). This drives the charge carrier away from CuS layer and leads to charge carrier concentration that has an increase function of x. Even at lowest concentration p(0), it is not a small value for this case (e.g., its value is 3.32×10¹⁹/cm³ for the case shown in FIG. 15). This explains why the polymer is a good conductor when forward voltage is applied. Again, it is Eq. 6 with constant electric field model used for the plot. The points demonstrated are independent of constant electric field assumption.

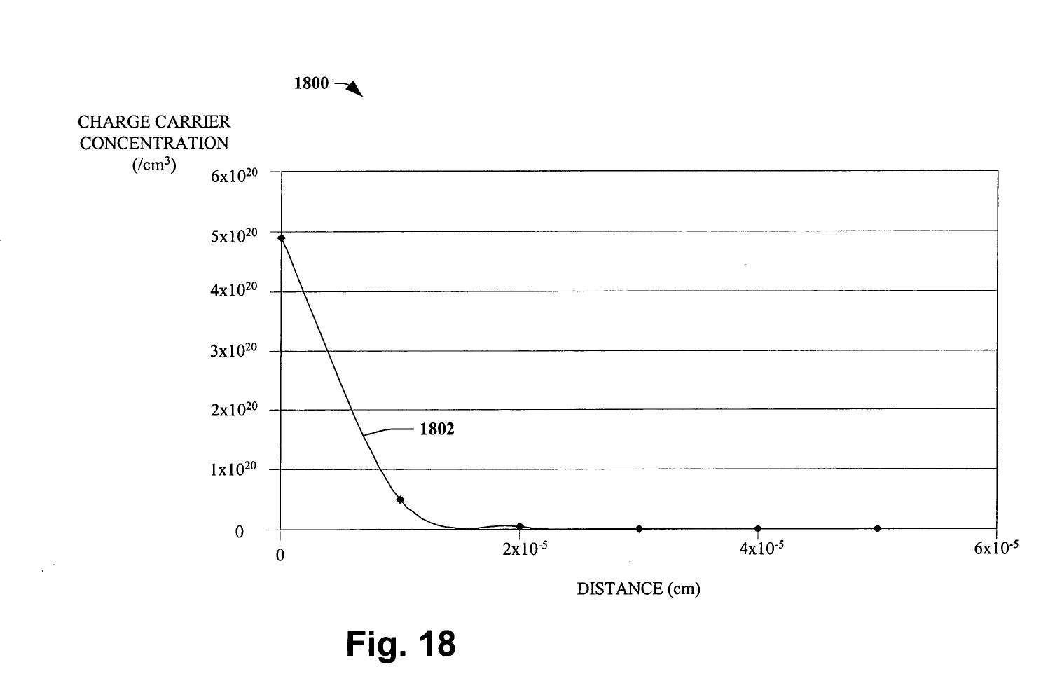

FIG. 18 depicts yet another graph 1800 of charge carrier distribution 1802 of the exemplary memory cell as a function of distance from the CuS and organic polymer interface in accordance with an aspect of the invention. For this graph, the parameters are set such that the reverse voltage=0.28V and the current J=0. With reversed voltage, the charge carrier is concentrated at the CuS polymer interface and drops quickly to small concentration when it is away from the interface, which describes why the memory cell becomes non-conductive when high reversed voltage applied. Again, Eq. 6 with constant electric field model is assumed for the plot. The points demonstrated are independent of this assumption.

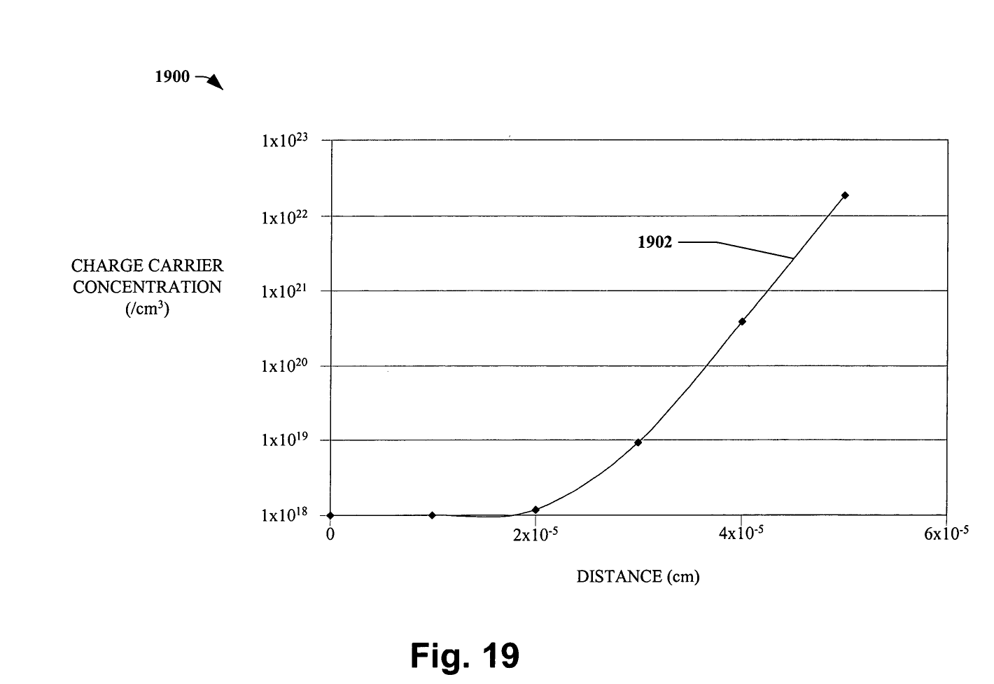

Referring now to FIG. 19, another graph 1900 that depicts charge carrier distribution 1902 of the exemplary memory cell as a function of distance in accordance with an aspect of the present invention is provided. For this graph 1900, parameters are set as follows: forward voltage=0.52V and current flux J>0 (p_{J}=10¹⁸/cm³). When current flux J>0, the charge carrier is still an increase function of x because the forward voltage drives the charge carrier away from CuS interface. One important point is that the lowest concentration p(x) is at interface.

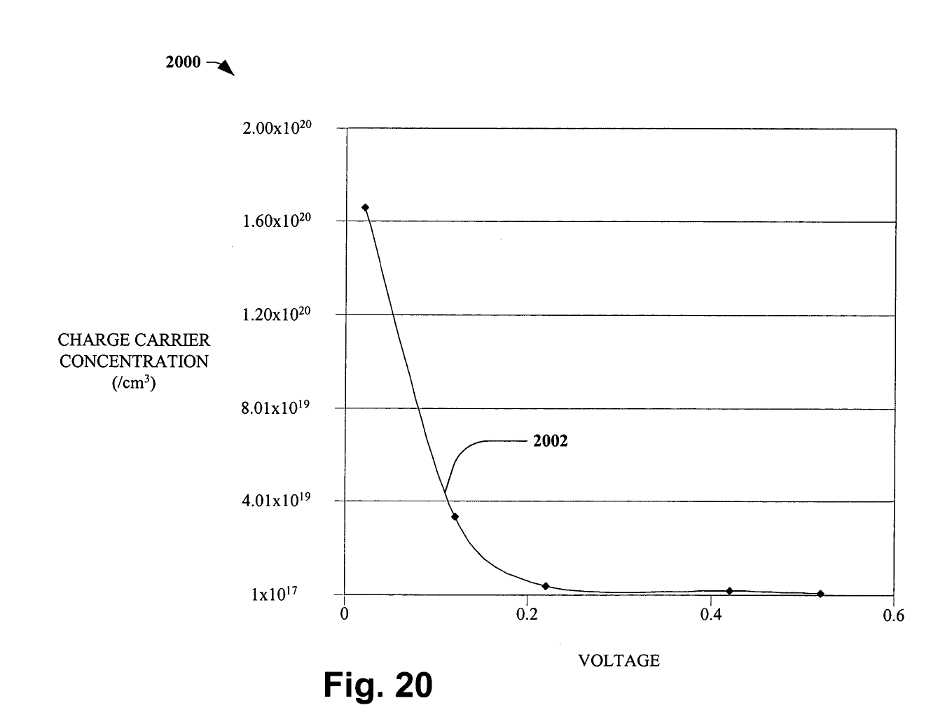

FIG. 20 depicts yet another graph 2000 of charge carrier concentration at interface 2002 of the exemplary memory cell as function of forward voltage V. For this graph, the parameters are set such that J>0 (p_{J}=10⁸/cm³) and assumes a constant electric field model. This model assumes the electric field in the cell is constant. Therefore, the voltage V(x) is described as a linear function. This model is applicable when the diffusion constant of the polymer is small and there is constant electric resistance. With this model, the charge carrier concentration at interface is derived as function of voltage. It is noted that p₀(V) tends to be constant after forward voltage is large enough and the current is controlled by the charge carrier not charge injection at the interface. As such, p(0) can be rewritten as:

$$p ( 0 ) = \frac{1}{2} \{ \begin{matrix}- {{K}_{eq} [ Polymer ]}_{0} + \\ \sqrt{{( {{K}_{eq} [ Polymer ]}_{0} )}^{2} + \frac{4 {ⅆ}_{CuS} {{{K}_{eq} [ Polymer ]}_{0} [ CuS ]}_{0}}{ⅆ}}\end{matrix} \} \qquad ( 10 )$$

This Eq. 10 shows that limiting p(0) is an increase function of thickness ratio between CuS layer and polymer layer.

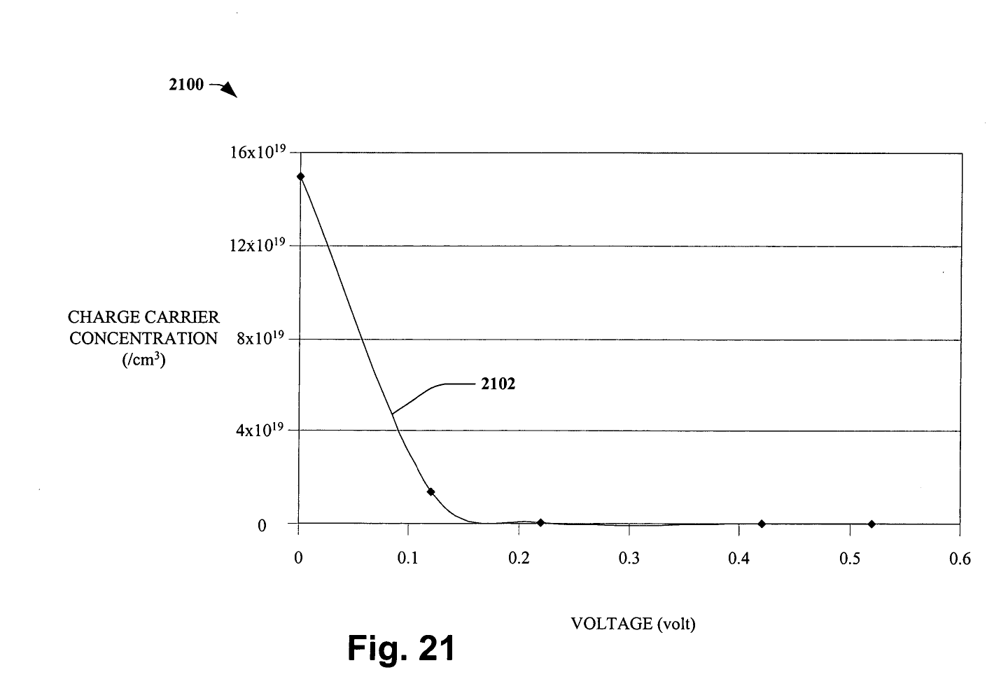

FIG. 21 illustrates another graph 2100 that depicts charge carrier concentration at the interface 2102 of the exemplary memory cell as function of forward voltage Vin accordance with an aspect of the present invention is provided. For this graph 2100, p(0) is a function of forward voltage, current J, which may or may not be>0, and a step potential function model. This model assumes the voltage V(x) function can be described by a step function. The model is applicable when the diffusion constant of the polymer is very large. Therefore, the electric resistance in the cell is trivial. With this model, the charge carrier concentration at interface is derived as the function of voltage. It is noted that in FIG. 21 that p₀(V) tends to be zero after forward voltage is large enough. When the charge carrier at the interface controls the current flux, this value is a function of voltage. This zero limit behavior is due to the interface boundary limit set by the reaction (1). Basically, the fast charge carrier transportation from the interface to the other end reaches the supply limit. Thus, the limiting p(0) is also rewritten as:

$$p ( 0 ) = \frac{1}{2} \{ \begin{matrix}- {{K}_{eq} [ Polymer ]}_{0} + \\ \sqrt{{( {{K}_{eq} [ Polymer ]}_{0} )}^{2} + \frac{4 {ⅆ}_{CuS} {{{K}_{eq} [ Polymer ]}_{0} [ CuS ]}_{0}}{ⅆ [ exp \frac{V ( 0 ) - V}{{V}_{t}} - \frac{V ( 0 ) - V}{{V}_{t}} ]}}\end{matrix} \} \qquad ( 11 )$$

Again p(0) is an increase function of thickness ratio between CuS layer and polymer layer.

Regarding the above discussion, it is important to note that the flux measured is determined by charge carrier drift when limiting flux is in the polymer. Under constant electric field assumption, the function to describe the charge carrier concentration is p(x). p_{J}=p(0) is met when the polymer determines limiting flux since the lowest concentration in the cell is at the interface. This condition results in a constant p(x). This means the diffusion contribution to the flux in Eq. 5 is zero. Under step potential assumption, another function is employed to describe the charge carrier concentration p(x). The initial charge carrier concentration p(0) has a relatively substantially smaller value than other regions. Therefore, J is still determined by p(0). Another point that is noted regards boundary conditions. Unlike semiconductors, it is just applicable to the concentration at interface, not everywhere. This boundary condition limits the total amount of the charge carrier produced in the cell.

The equations supra (E.q. 1-7) and the FIGS. 18-21 describe and model behavior of polymer memory cells. This model can be employed to explain measured data and can be for other materials aside from CuS. Additionally, the model can be used to think about how to improve retention and response time and to design the other devices such as transistors. Further, the model can be employed to develop various threshold voltages that set conductivity levels (e.g., set states), read conductivity levels and erase the conductivity levels thus performing memory cell operations of writing or programming, reading and erasing.

What has been described above are one or more aspects of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. In addition, while a particular feature of the invention may have been disclosed with respect to only one of several implementations, such feature may be combined with one or more other features of the other implementations as may be desired and advantageous for any given or particular application. Furthermore, to the extent that the term “includes” is used in either the detailed description and the claims, such term is intended to be inclusive in a manner similar to the term “comprising.”

1. A system for in-situ surface treatment in fashioning a memory cell comprising:
a gas distribution system that selectively provides a fluorine (F) based gas into a processing chamber; and
an excitation system that electrically excites the fluorine based gas to establish a plasma in the chamber which interacts with the surface to transform the surface from a conductive material into a passive layer that includes a conductivity facilitating compound having conductivity facilitating properties.

2. The system of claim 1 wherein the fluorine based gas includes at least one of CF₄ and SF₆.

3. The system of claim 1 wherein the passive layer includes at least one of copper sulfide (Cu₂S, CuS), copper oxide (CuO, Cu₂O), manganese oxide (MnO₂), titanium dioxide (TiO₂), indium oxide (I₃O₄), silver sulfide (Ag₂S, AgS) and iron oxide (Fe₃O₄).

4. The system of claim 1 wherein the surface is part of an upper portion of a deposition of conductive material placed within and exposed to the plasma by a trench formed within one or more layers of dielectric material spread across a wafer whereon the memory cell fashioning occurs.

5. The system of claim 1 wherein the passive layer has at least one of a thickness range of about 2 Å to about 0.1 μm, about 10 Å to about 0.01 μm and about 50 Å to about 0.005 μm.

6. The system of claim 1 wherein the passive layer has a refractive index from about 2.0 to 2.21.

7. The system of claim 1 wherein the passive layer has a resistivity of about 5.7×10⁻² Ohm/cm.

8. The system of claim 1 wherein the passive layer is transparent with a transmittance of about 60% between 600 and 700 nm.

9. The system of claim 4 wherein a stack formed on a substrate of the wafer comprises the memory cell and includes an organic layer formed over the passive layer and a conductive layer formed over the organic layer, the organic and conductive layers formed within the trench.

10. The system of claim 9 wherein the conductive material under the passive layer serves as a bottom electrode and the conductive layer overlying the organic layer serves as a top electrode.

11. The system of claim 9, the conductive material and the conductive layer including at least one of copper, aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, Hastelloy®, Kovar®, Invar, Monel®, Inconel®, brass, stainless steel and magnesium-silver alloy.

12. The system of claim 9, the conductive material and the conductive layer having at least one of thickness ranges of about 0.01 μm to about 10 μm, about 0.05 μm to about 5 μm, and about 0.1 μm to about 1 μm.

13. The system of claim 9, the organic layer including at least one of polyacetylene (cis or trans), polyphenylacetylene (cis or trans), polydiphenylacetylene, polyaniline, poly(p-phenylene vinylene), polythiophene, polyporphyrins, porphyrinic macrocycles, thiol derivatized polyporphyrins, polymetallocenes, polyferrocenes, polyphthalocyanines, polyvinylenes and polystiroles.

14. The system of claim 9, the organic layer having at least one of thickness ranges of about 0.001 μm to about 5 μm, about 0.01 μm to about 2.5 μm and about 0.05 μm to about 1 μm.

15. The system of claim 9, the dielectric material including at least one of silicon oxide (SiO), silicon dioxide (SiO₂), silicon nitride (Si₃N₄), (SiN), silicon oxynitride (SiOₓN_{y}), fluorinated silicon oxide (SiOₓF_{y}), polysilicon, amorphous silicon, tetraethyorthosilicate (TEOS), phosphosilicate glass (PSG) and borophosphosilicate glass (BPSG).

16. The system of claim 9 wherein a barrier layer at least partially surrounds the conductive material so as to mitigate diffusion of the conductive material into the dielectric material and/or substrate.

17. The system of claim 1 further comprising:
a measurement system that monitors the passive layer being formed;
a control system operatively coupled to the measurement system, gas distribution system and excitation system, the control system obtaining readings taken by the measurement and selectively adjusting at least one of the gas distribution system and excitation system in response thereto to facilitate at least one of forming the passive layer to a desired thickness, forming the passive layer at a desired rate, forming the passive layer to a desired composition and forming the passive layer at a desired location.

18. The system of claim 17 further comprising:
a temperature system that regulates the temperature within the chamber; and
a pressure system that regulates the pressure within the chamber, the control system operatively coupled to the temperature and pressure systems and selectively adjusting at least one thereof in response to readings taken by the measurement system.

19. The system of claim 18 wherein the measurement system is implemented utilizing at least one of optical interference, scatterometry, IR spectroscopy, ellipsometry, scanning electron microscopy, synchrotron and x-ray diffraction based techniques.

20. The system of claim 1 wherein the excitation system includes a voltage source.

21. A method of treating a surface in situ in fashioning a memory cell on a wafer comprising:
selectively providing a fluorine (F) based gas into a processing chamber;
exciting the fluorine based gas to generate a plasma; and
converting, via interaction with the plasma, the surface from a conductive material into a passive layer that includes a conductivity facilitating compound having conductivity facilitating properties.

22. The method of claim 21 further comprising:
measuring at least on of the thickness, rate of formation, composition and location of the passive layer being developed; and
selectively controlling in response to the measurements at least one of pressure within the chamber, temperature within the chamber, concentration of gases within the chamber, rate of flow of gases into the chamber, volume of gases distributed into the chamber and excitation provided within the chamber.

23. The method of claim 22 wherein the measurements are taken via at least one of optical interference, scatterometry, IR spectroscopy, ellipsometry, scanning electron microscopy, synchrotron and x-ray diffraction based techniques.

24. The method of claim 22 further comprising:
mapping the wafer into one or more grids; and
obtaining measurements at the grid mapped locations.

25. The method of claim 21 wherein the fluorine based gas includes at least one of CF₄ and SF₆.

26. The method of claim 21 wherein the passive layer includes at least one of copper sulfide (Cu₂S, CuS), copper oxide (CuO, Cu₂O), manganese oxide (MnO₂), titanium dioxide (TiO₂), indium oxide (I₃O₄), silver sulfide (Ag₂S, AgS) and iron oxide (Fe₃O₄), the method further comprising:
forming the passive layer to have at least one of a refractive index from about 2.0 to 2.21, a resistivity of about 5.7×10⁻² Ohm/cm, a transparency with a transmittance of about 60% between 600 and 700 nm and a thickness between about 200 to 600 nm.

27. The method of claim 21 wherein the surface is part of an upper portion of a deposition of conductive material placed within and exposed to the plasma by a trench formed within one or more layers of dielectric material spread across the wafer.

28. The method of claim 27 wherein a stack formed on a substrate of the wafer comprises the memory cell and includes an organic layer formed over the passive layer and a conductive layer formed over the organic layer, the organic and conductive layers formed within the trench.

29. The method of claim 28 wherein the conductive material under the passive layer serves as a bottom electrode and the conductive layer overlying the organic layer serves as a top electrode.

30. The method of claim 28, the conductive material and the conductive layer including at least one of copper, aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, Hastelloy®, Kovar®, Invar, Monel®, Inconel®, brass, stainless steel and magnesium-silver alloy.

31. The method of claim 28, the organic layer including at least one of polyacetylene (cis or trans), polyphenylacetylene (cis or trans), polydiphenylacetylene, polyaniline, poly(p-phenylene vinylene), polythiophene, polyporphyrins, porphyrinic macrocycles, thiol derivatized polyporphyrins, polymetallocenes, polyferrocenes, polyphthalocyanines, polyvinylenes and polystiroles.

32. The method of claim 28, the dielectric material including at least one of silicon oxide (SiO), silicon dioxide (SiO₂), silicon nitride (Si₃N₄), (SiN), silicon oxynitride (SiOₓN_{y}), fluorinated silicon oxide (SiOₓF_{y}), polysilicon, amorphous silicon, tetraethyorthosilicate (TEOS), phosphosilicate glass (PSG) and borophosphosilicate glass (BPSG).

33. The method of claim 28 further comprising:
forming a barrier layer that at least partially surrounds the conductive material so as to mitigate diffusion of the conductive material into the dielectric material and/or substrate.

34. A memory cell comprising:
a deposit of conductive material that serves as a bottom electrode, the bottom electrode formed on a substrate on a wafer and in a trench formed within a dielectric material spread across the wafer;
a passive layer having conductivity facilitating properties, the passive layer formed out of an upper portion of the bottom electrode via a plasma which interacts with the conductive material to convert the upper portion of the bottom electrode so as to include, at least, a conductivity facilitating compound, the plasma being generated from a fluorine (F) based gas and having access to the upper portion of the bottom electrode by way of the trench;
an organic layer formed over the passive layer; and
a layer of conductive material formed over the organic layer to serve as a top electrode.

35. The memory cell of claim 34 further comprising:
a barrier layer that at least partially surrounds the bottom electrode so as to mitigate diffusion of the conductive material into the dielectric material and/or substrate.

36. The memory cell of claim 34 wherein the bottom and top electrodes include at least one of copper, aluminum, chromium, germanium, gold, magnesium, manganese, indium, iron, nickel, palladium, platinum, silver, titanium, zinc, alloys thereof, indium-tin oxide, polysilicon, doped amorphous silicon, metal silicides, Hastelloy®, Kovar®, Invar, Monel®, Inconel®, brass, stainless steel and magnesium-silver alloy.

37. The memory cell of claim 34 wherein the organic layer includes at least one of polyacetylene (cis or trans), polyphenylacetylene (cis or trans), polydiphenylacetylene, polyaniline, poly(p-phenylene vinylene), polythiophene, polyporphyrins, porphyrinic macrocycles, thiol derivatized polyporphyrins, polymetallocenes, polyferrocenes, polyphthalocyanines, polyvinylenes and polystiroles.
